(19) United States
(12) Patent Application Publication
(10) Pub. No.: US 2024/0284714 A1
(43) Pub. Date: Aug. 22, 2024

(54) DISPLAY DEVICE

(71) Applicant: Samsung Display Co., Ltd., Yongin-si (KR)

(72) Inventors: YONG-HWAN PARK, Yongin-si (KR); GYUNG-MIN KO, Yongin-si (KR); SOYEON PARK, Yongin-si (KR); SEONGJUN LEE, Yongin-si (KR)

(73) Assignee: Samsung Display Co., Ltd., Yongin-si (KR)

(21) Appl. No.: 18/413,917

(22) Filed: Jan. 16, 2024

(30) Foreign Application Priority Data
Feb. 17, 2023 (KR) 10-2023-0021180

(51) Int. Cl. H10K 59/122; H10K 59/35; H10K 59/40

(52) U.S. Cl. CPC H10K 59/122; H10K 59/352; H10K 59/40

(57) ABSTRACT

A display device includes a display panel including first, second, and third emissive regions and an input sensing layer. The input sensing layer is disposed on the display panel and includes sensing parts. The sensing parts include first, second, and third openings that overlap the first, second, and third emissive regions, respectively, and a cut-away portion that connects the first opening and the second opening. A cut width A of the cut-away portion satisfies Inequality 1:

$$1 - \frac{L 2}{L 3} \leq \frac{A}{B} \leq 1 - \frac{L 1}{L 3}$$

Here, L1 is a length of the first emissive region in a direction, L2 is a length of the second emissive region in the direction, L3 is a length of the third emissive region in the direction, and B is a length by which the first emissive region and the second emissive region overlap each other in the direction.

### CROSS-REFERENCE TO RELATED APPLICATION(S)

This application claims priority to and benefits of Korean Patent Application No. 10-2023-0021180 under 35 U.S.C. § 119, filed on Feb. 17, 2023, in the Korean Intellectual Property Office, the entire contents of which are incorporated herein by reference.

### BACKGROUND

### 1. Technical Field

Embodiments relate to a display device including an input sensing layer.

### 2. Description of the Related Art

Multimedia devices, such as a television, a mobile phone, a tablet computer, a car navigation unit, a game machine, and the like, include a display device that displays an image for a user through a display screen. The display device may include a display panel that generates an image and an input sensor that senses a touch of the user.

The display panel of the display device may include pixels having a certain arrangement, and the arrangement of the pixels may be designed in various ways according to the size and purpose of the display device. Light generated from the pixels may cause various optical phenomena such as a resonance phenomenon or an interference phenomenon, and the degree/amount of the optical phenomena may vary according to the arrangement of the pixels. Furthermore, the optical phenomena may affect the display quality of the display device.

### SUMMARY

Embodiments provide a display device capable of improving display quality.

However, embodiments of the disclosure are not limited to those set forth herein. The above and other embodiments will become more apparent to one of ordinary skill in the art to which the disclosure pertains by referencing the detailed description of the disclosure given below.

According to an embodiment, a display device may include a display panel including first, second, and third emissive regions and an input sensing layer disposed on the display panel and including sensing parts. The sensing parts may include first, second, and third openings overlapping the first, second, and third emissive regions, respectively, and a cut-away portion connecting the first opening and the second opening. A cut width A of the cut-away portion may satisfy Inequality 1:

$$1 - \frac{L 2}{L 3} \leq \frac{A}{B} \leq 1 - \frac{L 1}{L 3}$$

In Inequality 1, L1 may be a length of the first emissive region in a direction, L2 may be a length of the second emissive region in the direction, L3 may be a length of the third emissive region in the direction, and B may be a length by which the first emissive region and the second emissive region overlap each other in the direction.

The first emissive region, the second emissive region, and the third emissive region may emit first color light, second color light, and third color light, respectively, and the first color light, the second color light, and the third color light may be different from one another.

A wavelength range of the third color light may be smaller than a wavelength range of the first color light and a wavelength range of the second color light.

The first emissive region and the second emissive region may be arranged along a first direction, and the third emissive region may be arranged along a second direction intersecting the first direction from the first emissive region and the second emissive region.

The direction may correspond to the first direction, and L1 may be less than or equal to L2.

The first, second, and third emissive regions may have first, second, and third widths, respectively, in the second direction, and a difference between the first width and the third width may be smaller than a difference between L1 and L3.

The cut width A may satisfy Equation 1:

$$\frac{A}{B} = 1 - \{ \frac{[ ( L 1 / L 3 ) + ( L 2 / L 3 ) ]}{2} \}$$

In Equation 1, L1, L2, L3, and B may be equal to L1, L2, L3, and B in Inequality 1.

Each of the first, second, and third emissive regions may extend in a first direction, and the first, second, and third emissive regions may be alternately arranged along a second direction intersecting the first direction.

The direction may correspond to the second direction, and L1 may be less than or equal to L2.

The first, second, and third emissive regions may have first, second, and third lengths, respectively, in the first direction, and a difference between the first length and the third length may be smaller than a difference between L1 and L3.

A gap between the first emissive region and the first opening may be substantially equal to a gap between the second emissive region and the second opening.

A gap between the first emissive region and the first opening may be greater than a gap between the second emissive region and the second opening.

The sensing parts may include mesh lines that surround the first, second, and third openings in a plan view, and the mesh lines may have the cut-away portion and may include a conductive material.

The sensing parts may further include a sub-conductive pattern layer that overlaps the cut-away portion, and the sub-conductive pattern layer may be disposed on a layer different from the mesh lines and may be connected to the mesh lines through a contact hole.

According to an embodiment, a display device may include a display panel including a plurality of pixel columns including first emissive regions, second emissive regions, and third emissive regions and an input sensing layer that is disposed on the display panel and that includes sensing parts. The sensing parts may include first openings, second openings, third openings, and cut-away portions. The first openings may overlap the first emissive regions, respectively, the second openings may overlap the second emissive regions, respectively, and the third openings may overlap the third emissive regions, respectively. Each of the cut-away portions may connect a first opening and a second opening adjacent to each other among the first openings and the second openings, and a cut width A of the cut-away portion may satisfy Inequality 1:

$$1 - \frac{L 2}{L 3} \leq \frac{A}{B} \leq 1 - \frac{L 1}{L 3}$$

In Inequality 1, L1 may be a length of the first emissive region in a direction, L2 may be a length of the second emissive region in the direction, L3 may be a length of the third emissive region in the direction, and B may be a length by which the first emissive region and the second emissive region overlap each other in the direction.

Each of the plurality of pixel columns may include the first emissive regions arranged along a first direction, the second emissive regions and the first emissive regions may be alternatively arranged along the first direction, and the third emissive regions spaced apart from the first emissive regions and the second emissive regions in a second direction intersecting the first direction and arranged along the first direction.

The sensing parts may include a mesh line in which the cut-away portions are not defined, and the mesh line may be disposed between the first emissive region and the second emissive region. Some of the first openings and the second openings adjacent to each other in the first direction may be spaced apart from each other with the mesh line disposed between the some of the first openings and the second openings adjacent to each other in the first direction.

The plurality of pixel columns may include an n^{th} pixel column and an (n+1)^{th} pixel column arranged along the second direction, where n is a natural number of 1 or larger. A position of the mesh line disposed in the n^{th} pixel column and a position of the mesh line disposed in the (n+1)^{th} pixel column may be different from each other in the second direction.

Each of the plurality of pixel columns may include the first emissive regions arranged along a first direction, the second emissive regions spaced apart from the first emissive regions in a second direction intersecting the first direction and arranged along the first direction, and the third emissive regions spaced apart from the first emissive regions in the second direction and arranged along the first direction.

The plurality of pixel columns may include an n^{th} pixel column and an (n+1)^{th} pixel column arranged along the second direction, where n is a natural number of 1 or larger. In the n^{th} pixel column, the second emissive regions may be disposed between the first emissive regions and the third emissive regions in the second direction. In the (n+1)^{th} pixel column, the first emissive regions may be disposed between the second emissive regions and the third emissive regions in the second direction.

### BRIEF DESCRIPTION OF THE DRAWINGS

The above and other objects and features of the disclosure will become apparent by describing in detail embodiments thereof with reference to the accompanying drawings.

FIG. 1 is a schematic perspective view of a display device according to an embodiment.

FIG. 2 is a schematic sectional view of a display module according to an embodiment.

FIG. 3 is a schematic plan view of a display panel according to an embodiment.

FIG. 4 is a schematic sectional view of the display panel according to an embodiment.

FIG. 5 is a schematic plan view of an input sensing layer according to an embodiment.

FIG. 6 is an enlarged schematic plan view of a sensing part according to an embodiment.

FIG. 7 is a schematic plan view of a mesh pattern layer before formation of a cut-away portion according to an embodiment.

FIGS. 8A and 8B are graphs depicting luminance ratios (%) depending on viewing angles (deg) of the display device including the mesh pattern layer of FIG. 7.

FIG. 9A is a schematic plan view of a mesh pattern layer according to an embodiment.

FIGS. 9B and 9C are enlarged schematic plan views of the mesh pattern layer corresponding to a region AA′ of FIG. 9A.

FIGS. 10A and 10B are graphs depicting luminance ratios (%) depending on viewing angles (deg) of the display device including the mesh pattern layers of FIGS. 9B and 9C, respectively.

FIG. 11A is a schematic plan view of a mesh pattern layer according to an embodiment.

FIG. 11B is an enlarged schematic plan view of the mesh pattern layer corresponding to a region BB′ of FIG. 11A.

FIG. 11C is an enlarged schematic plan view of the mesh pattern layer of FIG. 7.

FIG. 12A is a schematic sectional view of the display device corresponding to line I-I′ of FIG. 11B.

FIG. 12B is a schematic sectional view of a display device corresponding to line II-II′ of FIG. 11C.

FIG. 13 is a schematic sectional view of the display device corresponding to line III-III′ of FIG. 11B.

FIGS. 14A and 14B are schematic plan views of a mesh pattern layer according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, a display device according to an embodiment will be described with reference to the accompanying drawings.

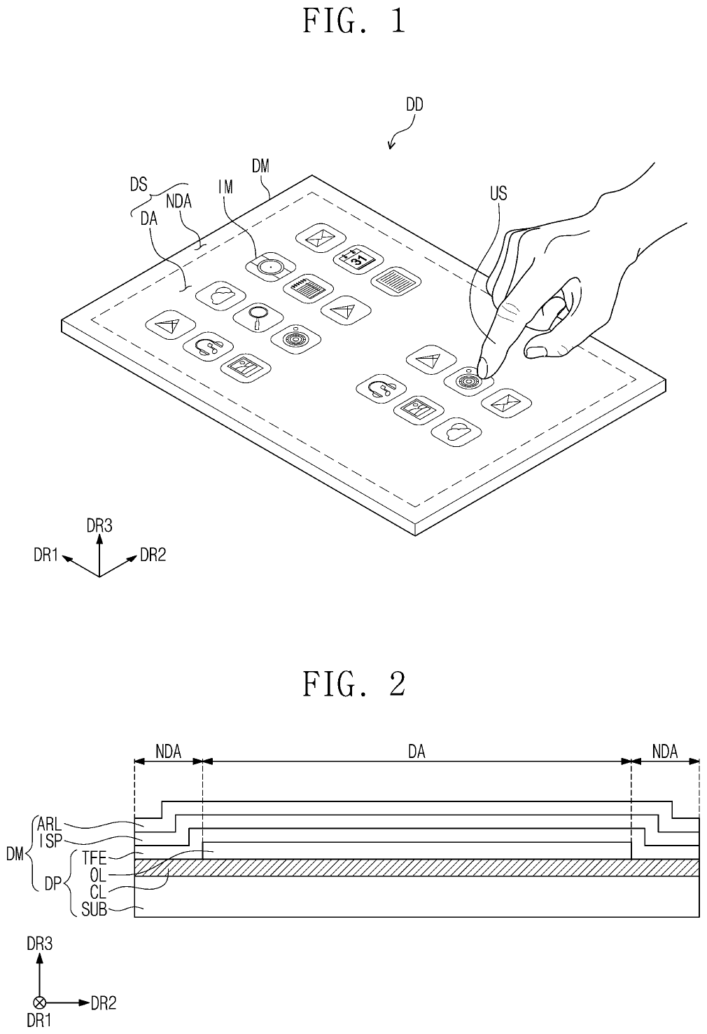

FIG. 1 is a schematic perspective view of the display device DD according to an embodiment.

The display device DD may be a device that is activated according to an electrical signal and that displays an image IM. For example, the display device DD may be a large device such as a television, a billboard, or the like, or may be a small and medium-sized device such as a monitor, a mobile phone, a tablet computer, a car navigation unit, a game machine, or the like. However, the aforementioned embodiments of the display device DD are examples, and the display device DD is not limited to any one as long as it does not deviate from the spirit and scope of the disclosure.

Referring to FIG. 1, the display device DD may include a display module DM that displays the image IM and senses an external input. In a plan view, the display module DM may have a rectangular shape with long sides extending in a first direction DR1 and short sides extending in a second direction DR2 intersecting the first direction DR1. However, without being limited thereto, the display module DM may have various shapes such as a circular shape, a polygonal shape, and the like.

In an embodiment, a third direction DR3 may be defined as a direction substantially perpendicular to the plane defined by the first direction DR1 and the second direction DR2. Front surfaces (or, upper surfaces) and rear surfaces (or, lower surfaces) of members constituting the display device DD may be opposite each other in the third direction DR3, and the normal directions of the front surfaces and the rear surfaces may be substantially parallel to the third direction DR3. Separation distances between the front surfaces and the rear surfaces defined in the third direction DR3 may correspond to the thicknesses of the members.

The expression “from above the plane” or “in a plan view” used herein may mean that it is viewed in the third direction DR3. The expression “on a section” used herein may mean that it is viewed in the first direction DR1 or the second direction DR2. For example, the directions indicated by the first, second, and third directions DR1, DR2, and DR3 may be relative concepts and may be changed to different directions.

The display device DD may be a rigid or flexible display device. The term “flexible” used herein may mean a property of being bent and may include everything from a structure that can be fully folded to a structure that can be bent to a level of several nanometers. For example, the flexible display device DD may include a curved display device, a rollable display device, a slidable display device, or a foldable display device.

An upper surface of the display device DD may be defined as a display surface DS, and the display surface DS may have a plane defined by the first direction DR1 and the second direction DR2. The display module DM may provide the generated image IM to a user through the display surface DS. The display surface DS may include a display area DA and a non-display area NDA.

The display area DA may display the image IM, and the non-display area NDA may not display the image IM. The non-display area NDA may be adjacent to the display area DA. For example, the non-display area NDA may surround the display area DA. The non-display area NDA may correspond to an area printed in a certain color and may define the border of the display module DM.

The display module DM may sense an input applied from outside the display module DM. The external input may include various types of inputs, such as force, pressure, temperature, light, and the like. In an embodiment, the external input is illustrated as the user's hand US applied to a front surface of the display device DD. However, this is an example, and the external input may include contact by a pen or an input (e.g., hovering) that is applied in proximity to the display device DD.

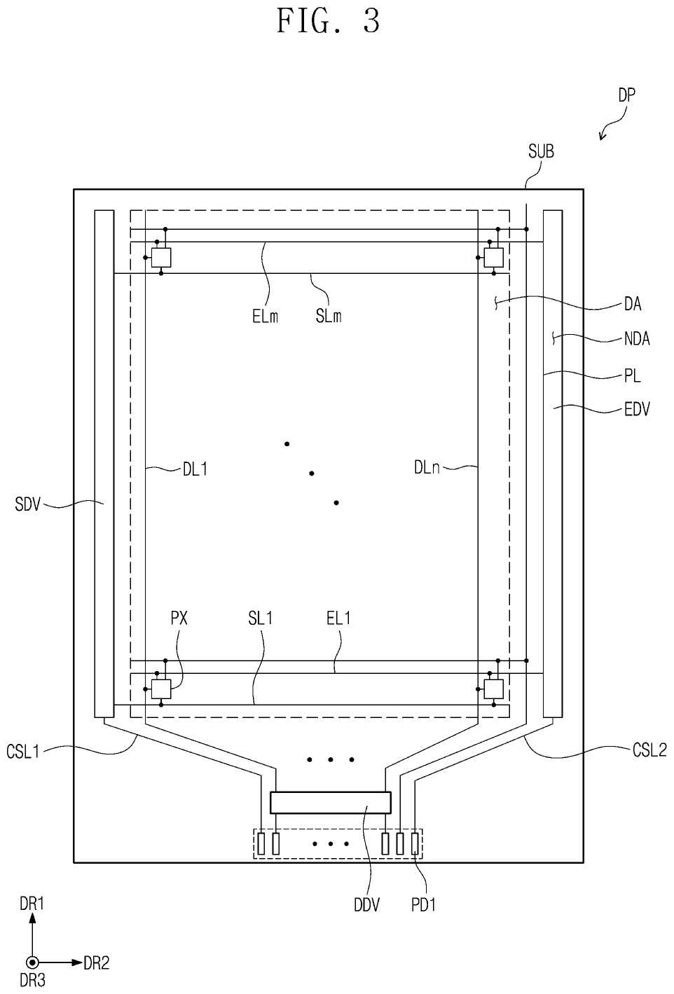

FIG. 2 is a schematic sectional view of the display module DM according to an embodiment.

Referring to FIG. 2, the display module DM may include a display panel DP, an input sensing layer ISP, and an anti-reflection layer ARL. The display panel DP may include a base substrate SUB, a circuit element layer CL, a display element layer OL, and a thin film encapsulation layer TFE.

The display panel DP according to an embodiment may be an emissive display panel, but embodiments are not limited thereto. For example, the display panel DP may be an organic light emitting display panel or an inorganic light emitting display panel. An emissive layer of the organic light emitting display panel may include an organic light emitting material. An emissive layer of the inorganic light emitting display panel may include quantum dots, quantum rods, and the like. Hereinafter, it will be considered that the display panel DP is an organic light emitting display panel.

The base substrate BS may provide a base surface on which the circuit element layer CL is disposed. The base substrate SUB may be a rigid substrate, or a flexible substrate that can be bent, folded, or rolled. The base substrate SUB may be a glass substrate, a metal substrate, or a polymer substrate. However, embodiments are not limited thereto, and the base substrate SUB may include an inorganic layer, an organic layer, or a composite layer.

The base substrate SUB may have a multi-layer structure. For example, the base substrate SUB may include synthetic resin layers and a single inorganic layer or multiple inorganic layers between the synthetic resin layers. The synthetic resin layers may include an acrylate-based resin, a methacrylate-based resin, a polyisoprene-based resin, a vinyl-based resin, an epoxy-based resin, a urethane-based resin, a celluose-based resin, a siloxane-based resin, a polyamide-based resin, and a perylene-based resin, but embodiments are not limited thereto.

The circuit element layer CL may be disposed on the base substrate SUB. The circuit element layer CL may include an insulating layer, a semiconductor pattern layer, and a conductive pattern layer. The insulating layer, the semiconductor pattern layer, and the conductive pattern layer included in the circuit element layer CL may form drive elements (e.g., a transistor), signal lines, and pads in the circuit element layer CL.

The display element layer OL may be disposed on the circuit element layer CL. The display element layer OL may include light emitting elements disposed in the display area DA. The light emitting elements may include an organic light emitting element, an inorganic light emitting element, a micro LED, or a nano LED, but embodiments are not limited thereto. The light emitting elements of the display element layer OL may be connected (e.g., electrically connected) to the drive elements of the circuit element layer CL and may generate light in the display area DA according to signals provided by the drive elements.

The thin film encapsulation layer TFE may be disposed on the display element layer OL and may seal the light emitting elements. The thin film encapsulation layer TFE may include at least one thin film for improving the optical efficiency of the display element layer OL or protecting the display element layer OL. The thin film encapsulation layer TFE may include at least one of an inorganic film and an organic film.

The input sensing layer ISP may be disposed on the display panel DP. The input sensing layer ISP may be formed, through a continuous process, on a base surface provided by the display panel DP. The input sensing layer ISP may be directly disposed on the display panel DP without a separate adhesive layer. However, without being limited thereto, the input sensing layer ISP may be coupled to the display panel DP through an adhesive layer.

The input sensing layer ISP may sense an external input and may provide an input signal including information about the external input such that the display panel DP displays an image corresponding to the external input. The input sensing layer ISP may be driven in various types such as a capacitive type, a resistive film type, an infrared type, a sound wave type, or a pressure type, and a driving type of the input sensing layer ISP is not limited to any one type as long as the input sensing layer ISP is capable of sensing an external input. In an embodiment, it is considered that the input sensing layer ISP is an input sensing panel driven in a capacitive type.

The anti-reflection layer ARL may be disposed on the input sensing layer ISP. For example, the anti-reflection layer ARL may be disposed (e.g., directly disposed) on the input sensing layer ISP. However, without being limited thereto, the anti-reflection layer ARL may be coupled with the input sensing layer ISP through an adhesive layer. The anti-reflection layer ARL may decrease the reflectance of external light incident from outside the display device DD (refer to FIG. 1).

In an embodiment, the anti-reflection layer ARL may include a phase retarder and/or a polarizer. The phase retarder and the polarizer may be provided in a film type or a liquid crystal coating type. The phase retarder and the polarizer may be provided in the form of one polarizer film.

In an embodiment, the anti-reflection layer ARL may include color filters. The color filters may be disposed to correspond to the arrangement and light emission colors of pixels included in the display panel DP. The color filters may filter external light incident toward the display panel into the same colors as those of light beams emitted by corresponding pixels. The anti-reflection layer ARL may further include a light blocking pattern layer disposed adjacent to the color filters.

Although FIG. 2 illustrates the embodiment in which the input sensing layer ISP and the anti-reflection layer ARL are sequentially disposed on the display panel DP, embodiments are not limited thereto. For example, the order in which the anti-reflection layer ARL and the input sensing layer ISP are stacked may be changed.

FIG. 3 is a schematic plan view of the display panel DP according to an embodiment.

Referring to FIG. 3, the display panel DP may include the base substrate SUB, pixels PX, signal lines SL1 to SLm, DL1 to DLn, EL1 to ELm, CSL1, CSL2, and PL connected (e.g., electrically connected) to the pixels PX, a scan driver SDV, a data driver DDV, and an emission driver EDV.

On a plane parallel to the first direction DR1 and the second direction DR2, the base substrate SUB may provide a base surface on which elements and lines of the display panel DP are disposed. The base substrate SUB may include the display area DA and the non-display area NDA of the display panel DP described above.

The display area DA may be a region (or an area) on which the pixels PX are disposed and that displays an image. The non-display area NDA may be a region (or an area) that is adjacent to the display area DA and on which an image is not displayed. The scan driver SDV, the data driver DDV, and the emission driver EDV for driving the pixels PX may be disposed on the non-display area NDA. However, to decrease the area of the non-display area NDA, at least one of the scan driver SDV, the data driver DDV, and the emission driver EDV may be disposed on the display area DA.

Each of the pixels PX may include a pixel drive circuit including transistors (e.g., a switching transistor and a drive transistor) and at least one capacitor and a light emitting element connected (e.g., electrically connected) to the pixel drive circuit. The pixels PX may emit light in response to electrical signals applied to the pixels PX and may display an image in the display area DA. Some of the pixels PX may include a transistor disposed on the non-display area NDA and are not limited to any one embodiment.

The signal lines SL1 to SLm, DL1 to DLn, EL1 to ELm, CSL1, CSL2, and PL may include the scan lines SL1 to SLm, the data lines DL1 to DLn, the emission lines EL1 to ELm, the first and second control lines CSL1 and CSL2, and the power line PL. Here, “m” and “n” are natural numbers.

The data lines DL1 to DLn may be insulated from the scan lines SL1 to SLm and the emission lines EL1 to ELm and may intersect the scan lines SL1 to SLm and the emission lines EL1 to ELm in a plan view. For example, the scan lines SL1 to SLm may extend in the second direction DR2 and may be connected (e.g., electrically connected) to the scan driver SDV. The data lines DL1 to DLn may extend in the first direction DR1 and may be connected (e.g., electrically connected) to the data driver DDV. The emission lines EL1 to ELm may extend in the second direction DR2 and may be connected (e.g., electrically connected) to the emission driver EDV.

The power line PL may include a portion extending in the first direction DR1 and a portion extending in the second direction DR2. The portion of the power line PL that extends in the first direction DR1 may be disposed on the non-display area NDA. The portion of the power line PL that extends in the second direction DR2 may be connected (e.g., electrically connected) to the pixels PX and the portion of the power line PL that extends in the first direction DR1. The portion of the power line PL that extends in the second direction DR2 may be disposed on a layer different from the portion extending in the first direction DR1 and may be connected thereto through a contact hole, or may be integral with the portion extending in the first direction DR1 on the same layer.

The first control line CSL1 may be connected (e.g., electrically connected) to the scan driver SDV. The second control line CSL2 may be connected (e.g., electrically connected) to the emission driver EDV.

First pads PD1 may be disposed adjacent to a lower end portion of the non-display area NDA. The first pads PD1 may be disposed to be closer to the lower end portion of the display panel DP than the data driver DDV. The first pads PD1 may be spaced apart from each other in the second direction DR2.

The first pads PD1 may be defined as display pads connected (e.g., electrically connected) to the pixels PX. Each of the first pads PD1 may be connected (e.g., electrically connected) to a corresponding one of the signal lines SL1 to SLm, DL1 to DLn, EL1 to ELm, CSL1, CSL2, and PL. For example, the first pads PD1 may be connected (e.g., electrically connected) to the power line PL, the first control line CSL1, the second control line CSL2, and the data lines DL1 to DLn, respectively.

The scan driver SDV may generate scan signals in response to a scan control signal. The scan signals may be applied to the pixels PX through the scan lines SL1 to SLm. The data driver DDV may generate data voltages corresponding to image signals in response to a data control signal. The data voltages may be applied to the pixels PX through the data lines DL1 to DLn. The emission driver EDV may generate emission signals in response to an emission control signal. The emission signals may be applied to the pixels PX through the emission lines EL1 to ELm.

The pixels PX may receive the data voltages in response to the scan signals. The pixels PX may display an image by emitting light having luminance corresponding to the data voltages in response to the emission signals. Light emission time of the pixels PX may be controlled by the emission signals.

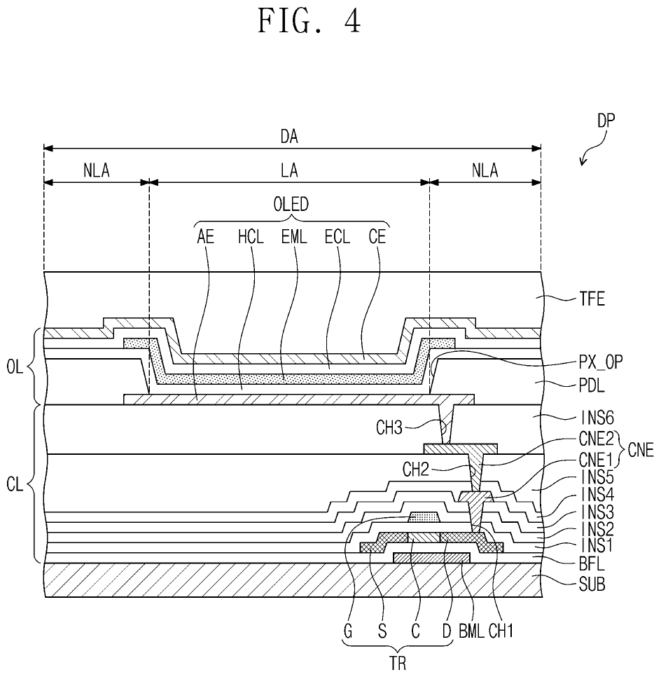

FIG. 4 is a schematic sectional view of the display panel DP according to an embodiment. FIG. 4 illustrates a section of the display panel DP corresponding to a representative pixel PX illustrated in FIG. 3.

Referring to FIG. 4, the pixel PX (refer to FIG. 3) may include a transistor TR and a light emitting element OLED. The transistor TR and the light emitting element OLED may be disposed on the base substrate SUB. Although FIG. 4 illustrates a single transistor TR, the pixel PX (refer to FIG. 3) may substantially include a plurality of transistors and at least one capacitor for driving the light emitting element OLED.

The circuit element layer CL may be disposed on the base substrate SUB. The circuit element layer CL may include a shield electrode BML, the transistor TR, connecting electrodes CNE, and insulating layers BFL and INS1 to INS6. The insulating layers BFL and INS1 to INS6 may include the buffer layer BFL and the first to sixth insulating layers INS1 to INS6. However, the stacked structure of the circuit element layer CL illustrated in FIG. 4 is an example, and the stacked structure of the circuit element layer CL may be changed according to a configuration of the pixel PX (refer to FIG. 3) and a process of the circuit element layer CL.

The shield electrode BML may be disposed on the base substrate SUB. The shield electrode BML may overlap the transistor TR. The shield electrode BML may protect the transistor TR by blocking light incident to the transistor TR from below the display panel DP. The shield electrode BML may include a conductive material. In an embodiment, the shield electrode BML may be connected (e.g., electrically connected) to the power line (refer to FIG. 3) and may receive a voltage. When the voltage is applied to the shield electrode BML, the threshold voltage of the transistor TR disposed over the shield electrode BML may be maintained. Without being limited thereto, the shield electrode BML may be a floating electrode. In another example, the shield electrode BML may be omitted.

The buffer layer BFL may be disposed on the base substrate SUB and may cover the shield electrode BML. The buffer layer BFL may include an inorganic layer. The buffer layer BFL may improve a coupling force between a semiconductor pattern layer or a conductive pattern layer disposed on the buffer layer BFL and the base substrate SUB.

The transistor TR may include a source S, a channel C, a drain D, and a gate G. The source S, the channel C, and the drain D of the transistor TR may be formed from the semiconductor pattern layer. The semiconductor pattern layer of the transistor TR may include poly silicon, amorphous silicon, or metal oxide and is not limited to any one as long as it has semiconductor properties.

The semiconductor pattern layer may include a plurality of regions distinguished according to the magnitude of conductivity. A region of the semiconductor pattern layer that is doped with a dopant or in which metal oxide is reduced may have high conductivity and may substantially function as a source electrode and a drain electrode of the transistor TR. The high-conductivity region of the semiconductor pattern layer may correspond to the source S and the drain D of the transistor TR. A low-conductivity region of the semiconductor pattern layer that is not doped or lightly doped or in which metal oxide is not reduced may correspond to the channel C (or, active layer) of the transistor TR.

The first insulating layer INS1 may be disposed on the buffer layer BFL and may cover the semiconductor pattern layer of the transistor TR. The gate G of the transistor TR may be disposed on the first insulating layer INS1. The gate G may overlap the channel C of the transistor TR. In an embodiment, the gate G may function as a mask in a process of doping the semiconductor pattern layer of the transistor TR.

The second insulating layer INS2 may be disposed on the first insulating layer INS1 and may cover the gate G. The third insulating layer INS3 may be disposed on the second insulating layer INS2.

The connecting electrodes CNE may include a first connecting electrode CNE1 and a second connecting electrode CNE2 for electrically connecting the transistor TR and the light emitting element OLED. However, embodiments of the connecting electrodes CNE that connect the transistor TR and the light emitting element OLED are not limited thereto, and one of first and second connecting electrodes CNE1 and CNE2 may be omitted, or an additional connecting electrode may be further included in the circuit element layer CL.

The first connecting electrode CNE1 may be disposed on the third insulating layer INS3. The first connecting electrode CNE1 may be connected (e.g., electrically connected) to the drain D through a first contact hole CH1 penetrating (or passing through) the first to third insulating layers INS1 to INS3. The fourth insulating layer INS4 may be disposed on the third insulating layer INS3 and may cover the first connecting electrode CNE1. The fifth insulating layer INS5 may be disposed on the fourth insulating layer INS4.

The second connecting electrode CNE2 may be disposed on the fifth insulating layer INS5. The second connecting electrode CNE2 may be connected (e.g., electrically connected) to the first connecting electrode CNE1 through a second contact hole CH2 penetrating (or passing through) the fourth and fifth insulating layers INS4 and INS5. The sixth insulating layer INS6 may be disposed on the fifth insulating layer INS5 and may cover the second connecting electrode CNE2.

Each of the first to sixth insulating layers INS1 to INS6 may include an inorganic layer or an organic layer. For example, the inorganic layer may include at least one of aluminum oxide, titanium oxide, silicon oxide, silicon oxy-nitride, zirconium oxide, and hafnium oxide. The organic layer may include at least one of an acrylate-based resin, a methacrylate-based resin, a polyisoprene-based resin, a vinyl-based resin, an epoxy-based resin, a urethane-based resin, a celluose-based resin, a siloxane-based resin, a polyamide-based resin, and a perylene-based resin.

The display element layer OL may include a pixel defining layer PDL and the light emitting element OLED. The light emitting element OLED may include a first electrode AE, a hole control layer HCL, an electron control layer ECL, an emissive layer EML, and a second electrode CE.

The first electrode AE may be disposed on the sixth insulating layer INS6. The first electrode AE may be connected (e.g., electrically connected) to the second connecting electrode CNE2 through a third contact hole CH3 penetrating (or passing through) the sixth insulating layer INS6. The first electrode AE may be connected (e.g., electrically connected) to the drain D of the transistor TR through the first and second connecting electrodes CNE1 and CNE2.

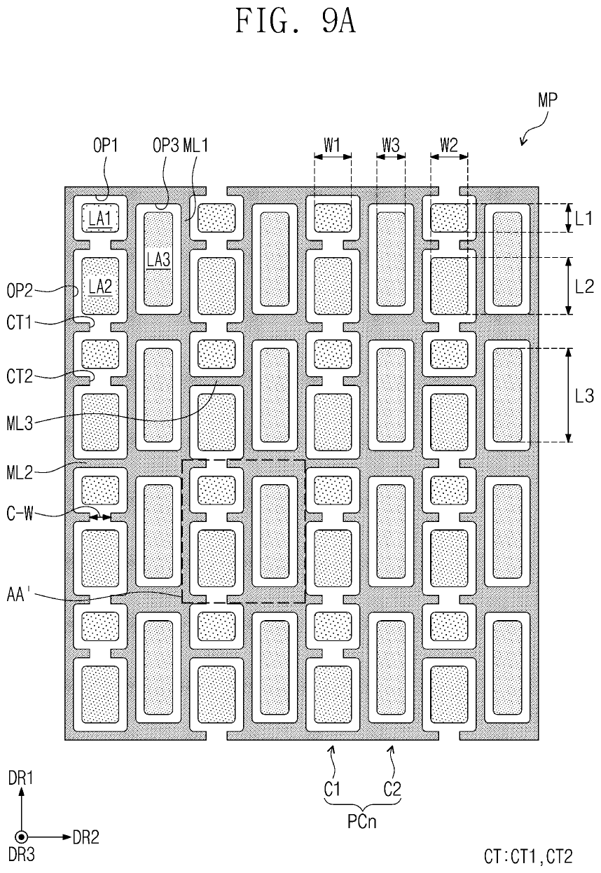

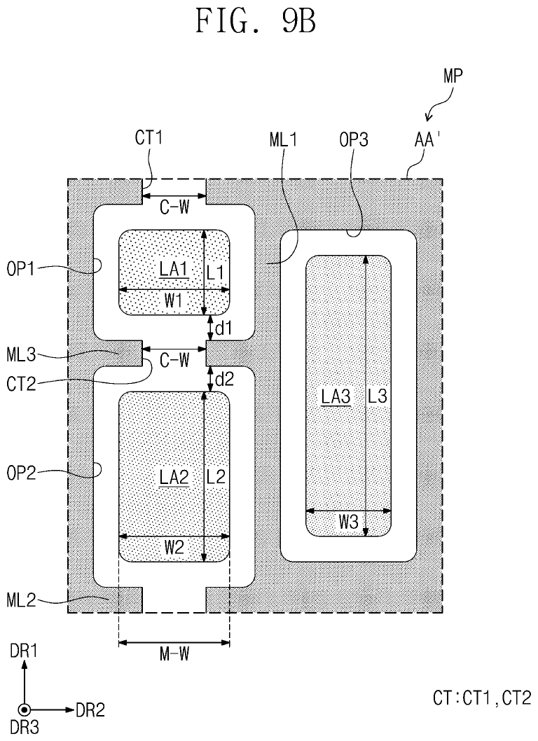

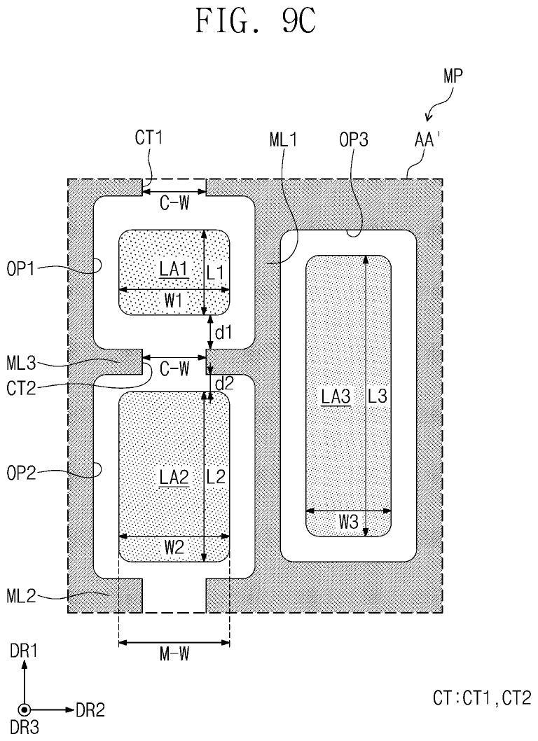

The pixel defining layer PDL may be disposed on the sixth insulating layer INS6. The pixel defining layer PDL may have a light emitting opening PX_OP defined therein to expose a portion of the first electrode AE. The portion of the first electrode AE exposed by the light emitting opening PX_OP may be defined as an emissive region LA. The emissive region LA may correspond to one of first to third emissive regions LA1, LA2, and LA3 (refer to FIG. 9A) that will be described below.

The region where the pixel defining layer PDL is disposed may correspond to a non-emissive region NLA. The non-emissive region NLA may surround the emissive region LA in the display area DA.

The hole control layer HCL may be disposed on the first electrode AE and the pixel defining layer PDL. The hole control layer HCL may be provided/formed as a common layer that overlaps the emissive region LA and the non-emissive region NLA. The hole control layer HCL may include at least one of a hole transport layer, a hole injection layer, and an electron blocking layer.

The emissive layer EML may be disposed on the hole control layer HCL. The emissive layer EML may be disposed in a region corresponding to the light emitting opening PX_OP. However, embodiments are not limited thereto, and the emissive layer EML may be provided/formed as a common layer. The emissive layer EML may include an organic material and/or an inorganic material. The emissive layer EML may generate one of red light, green light, and blue light.

The electron control layer ECL may be disposed on the emissive layer EML. The electron control layer ECL may be provided/formed as a common layer that overlaps the emissive region LA and the non-emissive region NLA. The electron control layer ECL may include at least one of an electron transport layer, an electron injection layer, and a hole blocking layer.

The second electrode CE may be disposed on the electron control layer ECL. The second electrode CE may be provided/formed as a common layer that overlaps the emissive region LA and the non-emissive region NLA. The second electrode CE may be commonly disposed for the pixels PX (refer to FIG. 3) and may apply a voltage to the pixels PX (refer to FIG. 3).

The thin film encapsulation layer TFE may be disposed on the second electrode CE and may cover the light emitting element OLED. The thin film encapsulation layer TFL may include a plurality of thin films. For example, the thin film encapsulation layer TFE may include inorganic films disposed on the second electrode CE and an organic film disposed between the inorganic films. The inorganic films of the thin film encapsulation layer TFE may protect the light emitting element OLED from moisture and/or oxygen, and the organic film of the thin film encapsulation layer TFE may protect the light emitting element OLED from foreign matter such as dust particles. However, embodiments of the thin film encapsulation layer TFE are not limited thereto.

A first voltage may be applied to the first electrode AE through the transistor TR, and a second voltage having a lower level than the first voltage may be applied to the second electrode CE. Holes and electrons injected into the emissive layer EML may be combined to form excitons, and as the excitons transit to a ground state, the light emitting element OLED may emit light.

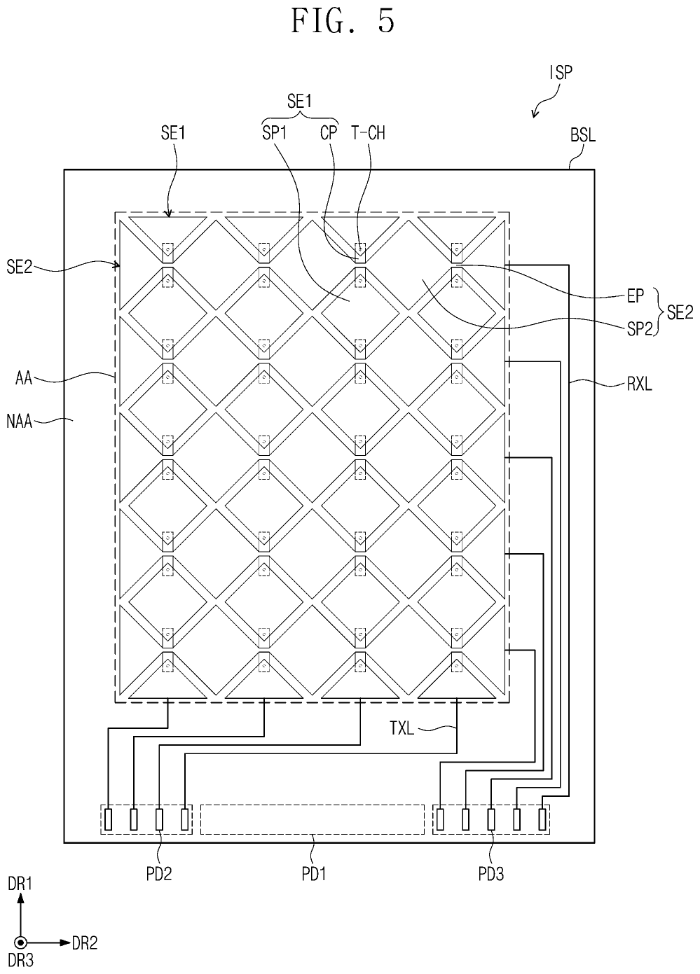

FIG. 5 is a schematic plan view of the input sensing layer ISP according to an embodiment.

The input sensing layer ISP may be disposed on the above-described display panel DP (refer to FIG. 3). The input sensing layer ISP may be formed (e.g., directly formed) on the base surface provided by the display panel DP (refer to FIG. 3). In an embodiment, the input sensing layer ISP may be driven in a mutual-capacitance type. However, without being limited thereto, the input sensing layer ISP may be driven in a self-capacitance type.

The input sensing layer ISP may include a base layer BSL, first sensing electrodes SE1, second sensing electrodes SE2, first sensing lines TXL, second sensing lines RXL, second pads PD2, and third pads PD3.

The base layer BSL may provide a base surface on which the electrodes and the lines of the input sensing layer ISP are disposed. In an embodiment, the base layer BSL may be disposed (e.g., directly disposed) on the thin film encapsulation layer TFE (refer to FIG. 4) of the display panel DP (refer to FIG. 4). However, without being limited thereto, the base layer BSL may be omitted, and the electrodes and the lines of the input sensing layer ISP may be disposed (e.g., directly disposed) on the thin film encapsulation layer TFE (refer to FIG. 4).

The base layer BSL may include an active region AA and a peripheral region NAA. The active region AA may overlap the display area DA (refer to FIG. 3), and the peripheral region NAA may overlap the non-display area NDA (refer to FIG. 3).

Each of the first sensing electrodes SE1 may extend in the first direction DR1, and the first sensing electrodes SE1 may be arranged in the second direction DR2. Although four first sensing electrodes SE1 are illustrated as an example in FIG. 5, the number of first sensing electrodes SE1 included in the input sensing layer ISP is not limited thereto. Each of the first sensing electrodes SE1 may include first sensing parts SP1 and connecting pattern layers CP that connect the first sensing parts SP1.

The first sensing parts SP1 may be arranged in the first direction DR1. Each of the connecting pattern layers CP may be disposed between the first sensing parts SP1 adjacent to each other in the first direction DR1 and may electrically connect the first sensing parts SP1. Each of the connecting pattern layers CP may extend in the first direction DR1. The connecting pattern layers CP may overlap the first sensing parts SP1 adjacent to each other in the first direction DR1 in a plan view. However, the shape of the connecting pattern layers CP is not limited to any one as long as the connecting pattern layers CP are capable of electrically connecting the first sensing parts SP1.

The connecting pattern layers CP may be disposed on a layer different from the first sensing parts SP1. The connecting pattern layers CP may be connected to corresponding first sensing parts SP1 through contact holes T-CH. The contact holes T-CH may be formed to penetrate an insulating layer disposed between the connecting pattern layers CP and the first sensing parts SP1.

Each of the second sensing electrodes SE2 may extend in the second direction DR2, and the second sensing electrodes SE2 may be arranged in the first direction DR1. Although five second sensing electrodes SE2 are illustrated as an example in FIG. 5, the number of second sensing electrodes SE2 included in the input sensing layer ISP is not limited thereto. Each of the second sensing electrodes SE2 may include second sensing parts SP2 and extending pattern layers EP that connect the second sensing parts SP2.

The second sensing parts SP2 may be arranged in the second direction DR2. Each of the extending pattern layers EP may be disposed between the second sensing parts SP2 adjacent to each other in the second direction DR2 and may electrically connect the second sensing parts SP2.

Each of the extending pattern layers EP may extend in the second direction DR2. The extending pattern layers EP may be insulated from the connecting pattern layers CP and may intersect the connecting pattern layers CP in a plan view. The extending pattern layers EP may extend from corresponding second sensing parts SP2. For example, the connecting pattern layers EP may be integral with the second sensing parts SP2 on the same layer.

The first sensing electrodes SE1 and the second sensing electrodes SE2 may be electrically insulated from each other and may intersect each other in a plan view. The input sensing layer ISP may sense an external input through a change in capacitance between the first sensing electrodes SE1 and the second sensing electrodes SE2. The first sensing electrodes SE1 and the second sensing electrodes SE2 may be disposed in the active region AA overlapping the display area DA (refer to FIG. 3). Accordingly, in case that an image is displayed through the display area DA (refer to FIG. 1), the display device DD (refer to FIG. 1) may sense an external input applied to the display area DA (refer to FIG. 1).

The first sensing lines TXL may be disposed on the peripheral region NAA and may be connected (e.g., electrically connected) to the first sensing electrodes SE1, respectively. For example, the first sensing lines TXL may be connected (e.g., electrically connected) to lower end portions of the first sensing electrodes SE1, respectively. The first sensing lines TXL may be disposed adjacent to a lower portion of the peripheral region NAA in a plan view. The first sensing lines TXL may extend from the lower end portions of the first sensing electrodes SE1 toward the second pads PD2, respectively.

The first sensing lines TXL may be connected (e.g., electrically connected) to the second pads PD2, respectively. The first sensing lines TXL may be disposed on a layer different from the second pads PD2 and may be connected to the second pads PD2 through contact holes, or may be integral with the second pads PD2 on the same layer.

The second sensing lines RXL may be disposed on the peripheral region NAA and may be connected (e.g., electrically connected) to the second sensing electrodes SE2, respectively. For example, the second sensing lines RXL may be connected (e.g., electrically connected) to right end portions of the second sensing electrodes SE2, respectively. The second sensing lines RXL may be disposed adjacent to a right side of the peripheral region NAA in a plan view. However, embodiments are not limited thereto, and the second sensing lines RXL may be disposed adjacent to a left side of the peripheral region NAA, or may be divided and disposed on the left and right sides of the peripheral region NAA. The second sensing lines RXL may extend from the right end portions of the second sensing electrodes SE2 toward the third pads PD3, respectively.

The second sensing lines RXL may be connected (e.g., electrically connected) to the third pads PD3, respectively. The second sensing lines RXL may be disposed on a layer different from the third pads PD3 and may be connected to the third pads PD3 through contact holes, or may be integral with the third pads PD3 on the same layer.

A touch controller for controlling the input sensing layer ISP may be connected (e.g., electrically connected) to the second pads PD2 and the third pads PD3 through a circuit board. The second pads PD2 and the third pads PD3 may be arranged in the second direction DR2. The second pads PD2 may be disposed adjacent to a lower left end portion of the peripheral region NAA in a plan view, and the third pads PD3 may be disposed adjacent to a lower right end portion of the peripheral region NAA in a plan view.

The first pads PD1 of the display panel DP (refer to FIG. 3) may be disposed between the second pads PD2 and the third pads PD3. The the first pads PD1, the second pads PD2, and the third pads PD3 may be disposed on substantially the same layer. However, without being limited thereto, the second pads PD2 and the third pads PD3 may be disposed on a layer different from the first pads PD1. The arrangement of the pads PD1, PD2, and PD3 illustrated in FIGS. 3 and 5 is an example, and embodiments are not limited thereto.

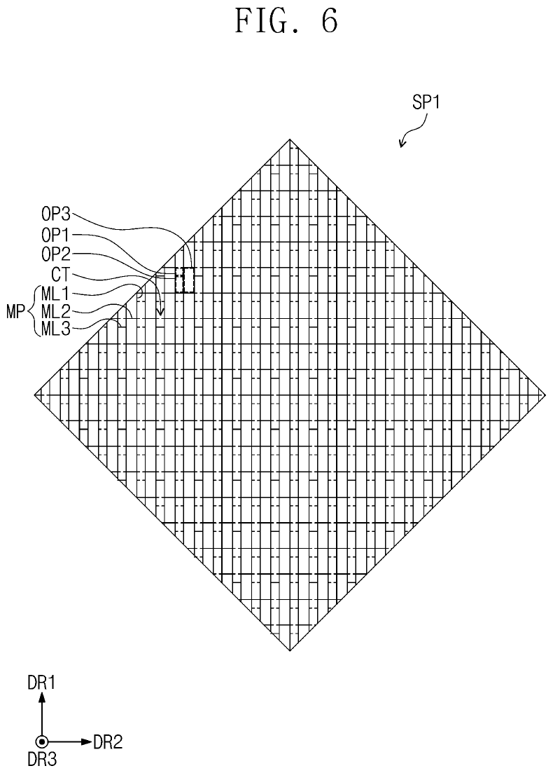

FIG. 6 is an enlarged schematic plan view of a sensing part SP1 according to an embodiment. FIG. 6 illustrates the first sensing part SP1 of the input sensing layer ISP (refer to FIG. 5). Description of the first sensing part SP1 that will be given below may be applied to the second sensing part SP2 (refer to FIG. 5).

Referring to FIG. 6, the first sensing part SP1 may include a mesh pattern layer MP. The mesh pattern layer MP may include a conductive material. The mesh pattern layer MP may include mesh lines ML1, ML2, and ML3 that define two or more different openings OP1, OP2, and OP3. The openings OP1, OP2, and OP3 may be defined by being surrounded by the mesh lines ML1, ML2, and ML3.

The mesh lines ML1, ML2, and ML3 may include the first mesh lines ML1, the second mesh lines ML2, and the third mesh lines ML3. The first mesh lines ML1, the second mesh lines ML2, and the third mesh lines ML3 may be connected (e.g., electrically connected) together and may have an integral shape.

Each of the first mesh lines ML1 may extend in the first direction DR1, and the first mesh lines ML1 may be arranged in the second direction DR2. Each of the second mesh lines ML2 may extend in the second direction DR2, and the second mesh lines ML2 may be arranged in the first direction DR1. The second mesh lines ML2 may have an integral shape that intersects the first mesh lines ML1 in a plan view. Each of the third mesh lines ML3 may extend in the second direction DR2, and the third mesh lines ML3 may be arranged in the first direction DR1 and the second direction DR2. The third mesh lines ML3 may alternate with the second mesh lines ML2 in the first direction DR1. The third mesh lines ML3 may be spaced apart from each other in the second direction DR2, and the third opening OP3 may be disposed between the third mesh lines ML3.

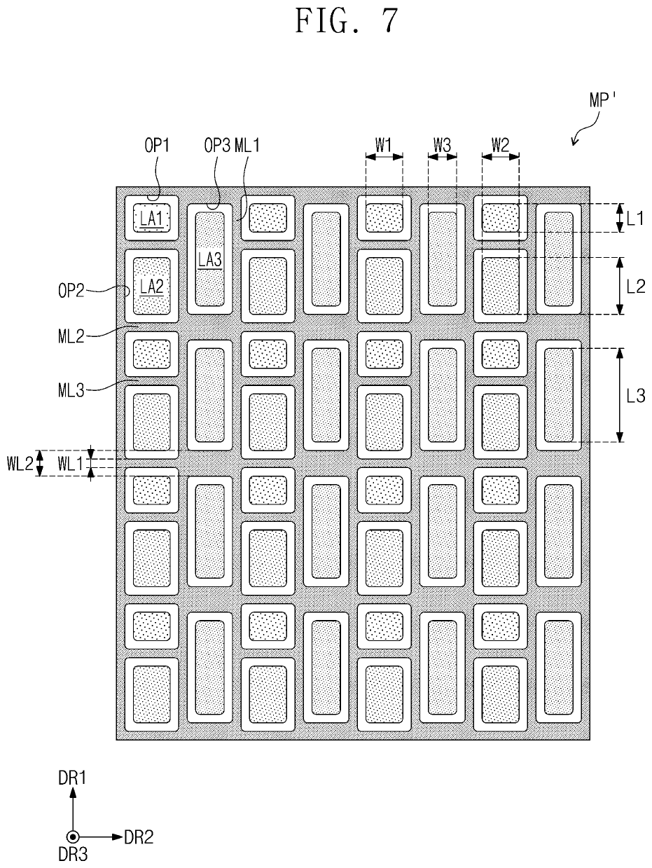

The mesh pattern layer MP may include the first to third openings OP1, OP2, and OP3 defined by the first to third mesh lines ML1, ML2, and ML3. The first to third openings OP1, OP2, and OP3 may have different areas in a plan view. For example, among the first to third openings OP1, OP2, and OP3, the third opening OP3 may have the largest planar area, and the first opening OP1 may have the smallest planar area. The regions in which the first to third openings OP1, OP2, and OP3 are defined may be regions overlapping first to third emissive regions LA1, LA2, and LA3 (refer to FIG. 7) that will be described below. Since the first to third openings OP1, OP2, and OP3 are defined in the mesh pattern layer MP, the first sensing part SP1 may not deteriorate the light emission efficiency of the first to third emissive regions LA1, LA2, and LA3 (refer to FIG. 7).

Each of the first opening OP1 and the second opening OP2 may be defined by being surrounded by the second mesh line ML2 and the third mesh line ML3 adjacent to each other in the first direction DR1 and the first mesh lines ML1 adjacent to each other in the second direction DR2. The first openings OP1 and the second openings OP2 may be alternately formed in the first direction DR1. A corresponding one of the third mesh lines ML3 may be disposed between the first opening OP1 and the second opening OP2.

The third opening OP3 may be defined by being surrounded by the second mesh lines ML2 adjacent to each other in the first direction DR1 and the first mesh lines ML1 adjacent to each other in the second direction DR2. The third openings OP3 may be disposed in the first direction DR1, and a portion of a corresponding one of the second mesh lines ML2 may be disposed between the third openings OP3.

The first openings OP1 and the second openings OP2 may be formed to alternate with the third openings OP3 in the second direction DR2. A single third opening OP3 may overlap the first opening OP1 and the second opening OP2 in the second direction DR2.

The shape of the mesh pattern layer MP illustrated in FIG. 6 is an example, and the arrangements and shapes of the first to third mesh lines ML1, ML2, and ML3 and the first to third openings OP1, OP2, and OP3 in the mesh pattern layer MP may be diversely changed according to the arrangement and shape of the pixels PX (refer to FIG. 3) of the display panel DP (refer to FIG. 3).

Cut-away portions CT may be defined in at least one of the first mesh lines ML1, the second mesh lines ML2, and the third mesh lines ML3. FIG. 6 illustrates an embodiment in which the cut-away portions CT are defined in the second mesh lines ML2 and the third mesh lines ML3. The cut-away portions CT may be formed by removing portions of the mesh lines. Each of the second mesh lines ML2 may include a plurality of portions spaced apart from each other in the second direction DR2 by the cut-away portions CT defined in the second mesh line ML2. Among the third mesh lines ML3, the third mesh line ML3 having the cut-away portion CT defined therein may include a plurality of portions spaced apart from each other in the second direction DR2 by the cut-away portion CT.

The cut-away portions CT may have an integral shape with adjacent openings among the openings OP1, OP2, and OP3. For example, the cut-away portions CT may be connected to the adjacent openings to form an integral space. For example, each of the cut-away portions CT may be defined in the second mesh lines ML2 or the third mesh lines ML3 and may have an integral shape with the first opening OP1 and the second opening OP2 adjacent thereto.

Since the cut-away portions CT are defined in at least one of the first mesh lines ML1, the second mesh lines ML2, and the third mesh lines ML3, blocking of light emitted through the emissive regions LA1, LA2, and LA3 (refer to FIG. 9A) by the mesh pattern layer MP may be reduced. For example, a luminance drop difference depending on viewing angles and light emission colors in a direction that is caused by a difference in length (or, width) between the emissive regions LA1, LA2, and LA3 (refer to FIG. 9A) in the direction may be reduced. Detailed description thereabout will be given below.

FIG. 7 is a schematic plan view of a mesh pattern layer MP′ before formation of a cut-away portion according to an embodiment. For convenience of description, the emissive regions LA1, LA2, and LA3 overlapping the mesh pattern layer MP′ are illustrated together in FIG. 7.

Referring to FIG. 7, the mesh pattern layer MP′ may be a component of the first sensing parts SP1 (refer to FIG. 5) or the second sensing parts SP2 (refer to FIG. 5) described above. The mesh pattern layer MP′ may include first mesh lines ML1, second mesh lines ML2, and third mesh lines ML3. The above description may be applied to the first to third mesh lines ML1, ML2, and ML3.

The display panel DP (refer to FIG. 4) may include the emissive regions LA1, LA2, and LA3. The display panel DP (refer to FIG. 4) may include the light emitting elements OLED (refer to FIG. 4), and the emissive regions LA1, LA2, and LA3 may correspond to the regions in which the light emitting elements OLED (refer to FIG. 4) are disposed. The emissive regions LA1, LA2, and LA3 may include the first to third emissive regions LA1, LA2, and LA3 distinguished from one another according to light emission colors. The first to third emissive regions LA1, LA2, and LA3 may be defined as regions in which first to third light emitting elements are disposed.

The first to third emissive regions LA1, LA2, and LA3 may emit light beams having different colors. For example, the first emissive region LA1 may emit red light, the second emissive region LA2 may emit green light, and the third emissive region LA3 may emit blue light. However, the colors of light beams emitted through the first to third emissive regions LA1, LA2, and LA3 are not limited thereto.

First emissive regions LA1, second emissive regions LA2, and third emissive regions LA3 may be provided. The first emissive regions LA1, the second emissive regions LA2, and the third emissive regions LA3 may be arranged in a certain arrangement in a plan view. The first emissive region LA1, the second emissive region LA2, and the third emissive region LA3 may be defined as one pixel unit. Pixel units, each of which includes the first emissive region LA1, the second emissive region LA2, and the third emissive region LA3, may be provided. The pixel units may be arranged in the first direction DR1 and the second direction DR2.

The first emissive regions LA1, the second emissive regions LA2, and the third emissive regions LA3 may be arranged in the first direction DR1 and the second direction DR2 in a plan view. The first emissive regions LA1 and the second emissive regions LA2 may be alternately arranged in the first direction DR1. The third emissive regions LA3 may be arranged in the first direction DR1 and may not overlap the first emissive regions LA1 or the second emissive regions LA2 in the first direction DR1. Each of the third emissive regions LA3 may overlap at least a portion of the first emissive region LA1 and at least a portion of the second emissive region LA2 in the second direction DR2. The first emissive regions LA1 and the third emissive regions LA3 may be alternately arranged in the second direction DR2, and the second emissive regions LA2 and the third emissive regions LA3 may be alternately arranged in the second direction DR2. However, the arrangement of the first to third emissive regions LA1, LA2, and LA3 illustrated in FIG. 7 is an example, and embodiments are not limited thereto.

The first emissive regions LA1 and the second emissive regions LA2 arranged in the first direction DR1 may be defined as a first light emission column, and the third emissive regions LA3 arranged in the first direction DR1 may be defined as a second light emission column. First light emission columns and second light emission columns may be provided. The first light emission columns and the second light emission columns may be alternately arranged in the second direction DR2.

The first to third emissive regions LA1, LA2, and LA3 may have various shapes in a plan view. For example, the first to third emissive regions LA1, LA2, and LA3 may have a polygonal shape (e.g., a quadrangular shape or an octagonal shape), a circular shape, or an oval shape. The shape of each of the first to third emissive regions LA1, LA2, and LA3 may correspond to the shape of the light emitting opening PX_OP (refer to FIG. 4) of the pixel defining layer PDL (refer to FIG. 4).

The first to third emissive regions LA1, LA2, and LA3 may have certain areas in a plan view. For example, the first to third emissive regions LA1, LA2, and LA3 may have different areas in a plan view. However, without being limited thereto, the first to third emissive regions LA1, LA2, and LA3 may have different lengths and widths, but may have substantially the same area. The areas of the first to third emissive regions LA1, LA2, and LA3 may be designed in various ways according to light emission colors, light emission efficiency, resolution, or the size of the display device DD (refer to FIG. 1).

The first to third mesh lines ML1, ML2, and ML3 may not overlap the emissive regions LA1, LA2, and LA3. The first to third mesh lines ML1, ML2, and ML3 may be disposed to overlap the non-emissive region NLA (refer to FIG. 4). First to third openings OP1, OP2, and OP3 defined by the first to third mesh lines ML1, ML2, and ML3 may overlap the first to third emissive regions LA1, LA2, and LA3, respectively.

The first to third openings OP1, OP2, and OP3 may have planar areas greater than the areas of the overlapping emissive regions. For example, the planar area of the first opening OP1 may be greater than the area of the first emissive region LA1, the planar area of the second opening OP2 may be greater than the area of the second emissive region LA2, and the planar area of the third opening OP3 may be greater than the area of the third emissive region LA3. Thus, the mesh pattern layer MP′ may not decrease the light emission efficiency of light emitted through the emissive regions LA1, LA2, and LA3.

The first mesh lines ML1 may extend in the first direction DR1 and may be arranged in the second direction DR2. The first mesh lines ML1 may be disposed between the first emissive regions LA1 and the second emissive regions LA2 arranged in the first direction DR1 (e.g., the first light emission column) and the third emissive regions LA3 arranged in the first direction DR1 (e.g., the second light emission column).

The second mesh lines ML2 may extend in the second direction DR2 and may be arranged in the first direction DR1. The second mesh lines ML2 may have an integral shape that intersects the first mesh lines ML1 in a plan view. For example, the second mesh lines ML2 may have a shape extending from the first mesh lines ML1 in the second direction DR2. The second mesh lines ML2 may be disposed between the first emissive region LA1 and the second emissive regions LA2 facing each other in the first direction and the third emissive regions LA3 facing each other in the first direction DR1.

The second mesh line ML2 may include portions having different line widths. For example, a first portion of the second mesh line ML2 disposed between the first emissive region LA1 and the second emissive region LA2 may have a first line width WL1, and a second portion of the second mesh line ML2 disposed between the third emissive regions LA3 may have a second line width WL2. The second line width WL2 may be greater than the first line width WL1. This may vary according to the areas of the emissive regions LA1, LA2, and LA3 and the gaps between the emissive regions LA1, LA2, and LA3. Embodiments are not limited thereto, and the first line width WL1 and the second line width WL2 may be substantially the same as each other.

The third mesh lines ML3 may extend in the second direction DR2 and may be arranged in the first direction DR1 and the second direction DR2. The third mesh lines ML3 may have an integral shape that is integral with the first mesh lines ML1. The third mesh lines ML3 may have a shape extending from the first mesh lines ML1 in the second direction DR2. The third mesh lines ML3 may be disposed between the first emissive region LA1 and the second emissive region LA2. The third emissive region LA3 may be disposed between the third mesh lines ML3 in the second direction DR2.

The arrangement and shapes of the first to third mesh lines ML1, ML2, and ML3 may be diversely changed according to the arrangement and planar areas of the first to third openings OP1, OP2, and OP3 defined in the mesh pattern layer MP′. For example, the arrangement and planar areas of the first to third openings OP1, OP2, and OP3 may be diversely changed according to the arrangement and areas of the emissive regions LA1, LA2, and LA3.

For convenience of description, the first to third mesh lines ML1, ML2, and ML3 are distinguished from one another. However, the first to third mesh lines ML1, ML2, and ML3 may be connected (e.g., electrically connected) together and may have an integral shape. For example, the first to third mesh lines ML1, ML2, and ML3 may be formed by patterning the first to third openings OP1, OP2, and OP3 in an integral conductive layer.

The first to third emissive regions LA1, LA2, and LA3 may have certain lengths in the first direction DR1 and may have certain widths in the second direction DR2. The first emissive region LA1 may have a first length L1 in the first direction DR1 and may have a first width W1 in the second direction DR2. The second emissive region LA2 may have a second length L2 in the first direction DR1 and may have a second width W2 in the second direction DR2. The third emissive region LA3 may have a third length L3 in the first direction DR1 and may have a third width W3 in the second direction DR2.

The lengths L1, L2, and L3 of the first to third emissive regions LA1, LA2, and LA3 in the first direction DR1 may differ from one another. For example, the lengths may increase in the order of the first length L1, the second length L2, and the third length L3.

The first to third widths W1, W2, and W3 of the first to third emissive regions LA1, LA2, and LA3 in the second direction DR2 may differ from one another. For example, the widths may increase in the order of the third width W3, the second width W2, and the first width W1. The first width W1 may be greater than the second width W2, and the second width W2 may be greater than the third width W3. However, without being limited thereto, the first width W1 and the second width W2 may be substantially the same as each other. A difference between the first to third widths W1, W2, and W3 may not be greater than a difference between the first to third lengths L1, L2, and L3.

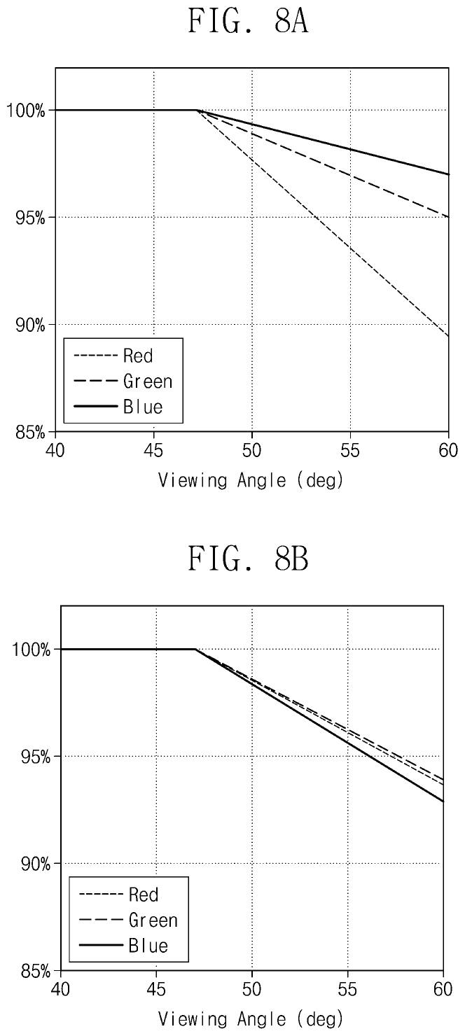

Due to the mesh pattern layer MP′ surrounding the first to third emissive regions LA1, LA2, and LA3, the difference between the lengths L1, L2, and L3 of the first to third emissive regions LA1, LA2, and LA3, and the difference between the first to third widths W1, W2, and W3 of the first to third emissive regions LA1, LA2, and LA3, the degree/amount of reduction in luminance depending on viewing angles in a specific direction may vary according to light emission colors. Detailed description thereabout will be given below with reference to FIGS. 8A and 8B together.

FIGS. 8A and 8B are graphs depicting luminance ratios (%) depending on viewing angles (deg) of the display device including the mesh pattern layer MP′ of FIG. 7. In this specification, a viewing angle represents an angle between measurement points where the display device DD (refer to FIG. 1) is viewed from a reference axis parallel to the third direction DR3. Furthermore, the luminance ratios depending on the viewing angles were measured based on the fact that the first to third emissive regions LA1, LA2, and LA3 emit red light, green light, and blue light, respectively.

FIG. 8A illustrates luminance ratios of light beams emitted from the first to third emissive regions LA1, LA2, and LA3 depending on viewing angles in a direction parallel to the first direction DR1. FIG. 8B illustrates luminance ratios of light beams emitted from the first to third emissive regions LA1, LA2, and LA3 depending on viewing angles in a direction parallel to the second direction DR2. Referring to FIGS. 7, 8A, and 8B, the luminance ratios depending on color light beams in the first direction DR1 and the second direction DR2 may decrease at a viewing angle of about 47 degrees or more. The viewing angle at which the luminance ratios start to decrease may vary according to the design of the display device DD (refer to FIG. 1).

Due to the difference between the first to third lengths L1, L2, and L3 of the first to third emissive regions LA1, LA2, and LA3, the degrees of reduction in the luminance ratios in the first direction DR1 may differ from one another. For example, since red light is output through the first emissive region LA1 having the smallest length (e.g., the first length L1) in the first direction DR1, the degree/amount of reduction in the luminance ratio of red light may be greatest. Furthermore, since blue light is output through the third emissive region LA3 having the greatest length (e.g., the third length L3) in the first direction DR1, the degree/amount of reduction in the luminance ratio of blue light may be smallest.

For example, due to the difference between the first to third widths W1, W2, and W3 of the first to third emissive regions LA1, LA2, and LA3 in the second direction DR2, the degrees of reduction in the luminance ratios in the second direction DR2 may differ from one another. For example, in the second direction DR2, the degree/amount of reduction in the luminance ratio of blue light may be greatest, and the degrees of reduction in the luminance ratios of red light and green light may be substantially similar to or the same as each other.

Referring to FIGS. 7 and 8B, since the difference between the first to third widths W1, W2, and W3 of the first to third emissive regions LA1, LA2, and LA3 in the second direction DR2 is not large, a deviation between the degrees of luminance ratio reduction (or, the degrees of luminance drop) depending on color light beams in the second direction DR2 may not be large. Accordingly, a white angular dependency (WAD) deviation in the second direction DR2 may not be large.

However, referring to FIGS. 7 and 8A, since the difference between the first to third lengths L1, L2, and L3 of the first to third emissive regions LA1, LA2, and LA3 in the first direction DR1 is large, a deviation between the degrees of luminance ratio reduction (or, the degrees of luminance drop) depending on color light beams in the first direction DR1 may be large. Thus, a white angular dependency (WAD) deviation in the first direction DR1 may increase, and therefore the display quality may be degraded.

To solve the problem that the WAD deviation increases depending on the directions in which the display device DD (refer to FIG. 1) is viewed and the viewing angles, the cut-away portions CT (refer to FIG. 9A) may be formed in the mesh pattern layer MP (refer to FIG. 9A). Detailed description thereabout will be given below with reference to the following drawings.

FIG. 9A is a schematic plan view of the mesh pattern layer MP according to an embodiment. FIGS. 9B and 9C are enlarged plan views of the mesh pattern layer MP corresponding to a region AA′ of FIG. 9A. FIGS. 9A, 9B, and 9C illustrate the mesh pattern layer MP having the cut-away portions CT formed therein, and the above description may be applied to the cut-away portions CT.

Referring to FIG. 9A, the cut-away portions CT may be defined in at least some of the first to third mesh lines ML1, ML2, and ML3 of the mesh pattern layer MP. The cut-away portions CT may be formed in consideration of a deviation between the degrees of luminance ratio drop depending on directions and color light beams.

For example, the first mesh lines ML1 of the mesh pattern layer MP that extend in the first direction DR1 and that are arranged in the second direction DR2 may affect a reduction in a luminance ratio depending on viewing angles in the second direction DR2. Since the difference between the first to third widths W1, W2, and W3 of the first to third emissive regions LA1, LA2, and LA3 in the second direction DR2 is not large, a deviation between the degrees of luminance ratio drop depending on color light beams in the second direction DR2 may not be large (refer to FIG. 8B). Accordingly, the cut-away portions CT may not be formed in the first mesh lines ML1.

The second mesh lines ML2 and the third mesh lines ML3 of the mesh pattern layer MP that extend in the second direction DR2 and that are arranged in the first direction DR1 may affect a reduction in a luminance ratio depending on viewing angles in the first direction DR1. Since the difference between the first to third lengths L1, L2, and L3 of the first to third emissive regions LA1, LA2, and LA3 in the first direction DR1 is relative large, a deviation between the degrees of luminance ratio drop depending on color light beams in the first direction DR1 may be large (refer to FIG. 8A). Accordingly, the cut-away portions CT may be formed in at least portions of the second mesh lines ML2 and the third mesh lines ML3.

The cut-away portions CT may be formed in the mesh pattern layer MP. Among the cut-away portions CT, cut-away portions formed in the second mesh lines ML2 may be defined as first cut-away portions CT1, and cut-away portions formed in the third mesh lines ML3 may be defined as second cut-away portions CT2. The first cut-away portions CT1 and the second cut-away portions CT2 may have cut widths C-W in the second direction DR2. The cut widths C-W may correspond to the sizes of portions that are removed from the second mesh lines ML2 or the third mesh lines ML3 to form the cut-away portions CT.

Referring to FIG. 9B, the cut widths C-W of the first cut-away portions CT1 and the cut widths C-W of the second cut-away portions CT2 may be equal to each other. The cut widths C-W may vary depending on the first length L1 and the first width W1 of the first emissive region LA1, the second length L2 and the second width W2 of the second emissive region LA2, and the third length L3 of the third emissive region LA3. For example, the cut widths C-W may be set to be inversely proportional to a difference in length between the first emissive region LA1 and the third emissive region LA3 (e.g., a difference between the first length L1 and the third length L3) and a difference in length between the second emissive region LA2 and the third emissive region LA3 (e.g., a difference between the second length L2 and the third length L3).

The ratio of the cut width C-W to a mesh width M-W in the second direction DR2 may satisfy the range of Inequality 1 below. In an embodiment, the mesh width M-W may correspond to the length by which the first emissive region LA1 and the second emissive region LA2 overlap each other in the first direction DR1. For example, the mesh width M-W may be equal to the first width W1 or the second width W2. In Inequality 1 below, “L1”, “L2”, and “L3” correspond to the first length L1, the second length L2, and the third length L3, respectively.

$$1 - \frac{L 2}{L 3} \leq \frac{Cut Width ( C - W )}{Mesh Width ( M - W )} \leq 1 - \frac{L 1}{L 3} \qquad [ Inequality 1 ]$$

In an embodiment, the ratio of the cut width C-W to the mesh width M-W in the second direction DR2 may satisfy Equation 1 below. In Equation 1 below, “L1”, “L2”, and “L3” correspond to the first length L1, the second length L2, and the third length L3, respectively.

$$\frac{Cut Width ( C - W )}{Mesh Width ( M - W )} = 1 - \{ \frac{( L 1 / L 3 ) + ( L 2 / L 3 )}{2} \} \qquad [ Equation 1 ]$$

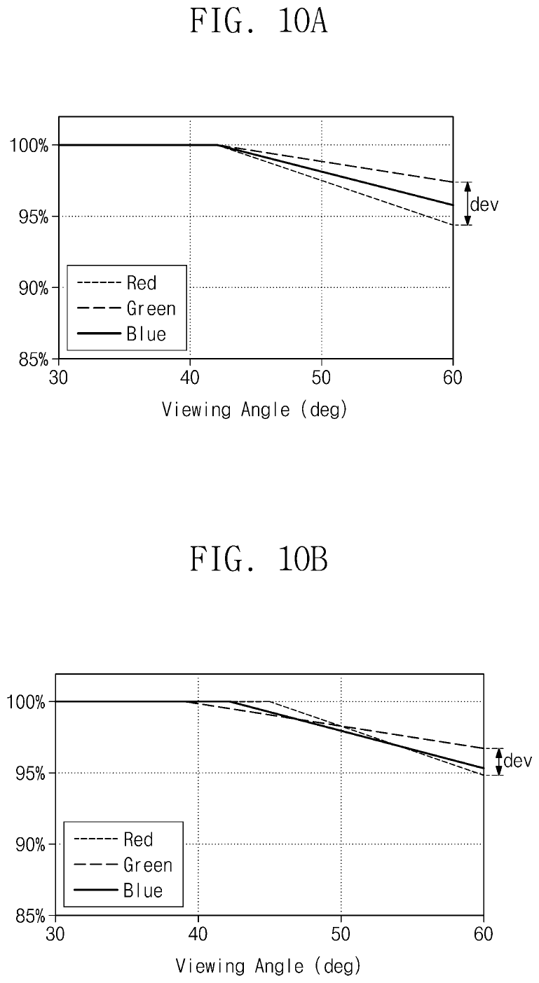

FIG. 10A is a graph depicting luminance ratios depending on viewing angles of the display device including the mesh pattern layer of FIG. 9B. FIG. 10A illustrates luminance ratios of light beams emitted from the first to third emissive regions LA1, LA2, and LA3 depending on viewing angles in a direction parallel to the first direction DR1.

Referring to FIGS. 9B and 10A, the first cut-away portion CT1 and the second cut-away portion CT2 may be formed in the second mesh line ML2 and the third mesh line ML3 that are adjacent to the first emissive region LA1 and the second emissive region LA2, and thus the degree/amount of reduction in the luminance ratio of red light and the degree/amount of reduction in the luminance ratio of green light in the first direction DR1 may be reduced. For example, as compared to those in the embodiment of the mesh pattern layer MP′ (refer to FIG. 7) before the formation of the cut-away portions CT (refer to FIG. 8A), the degree/amount of reduction in the luminance ratio of red light and the degree/amount of reduction in the luminance ratio of green light may be reduced by the cut-away portions CT.

For example, since the cut width C-W is designed in consideration of the ratio of the first length L1 to the third length L3 and the ratio of the second length L2 to the third length L3, the degree/amount of reduction in the luminance ratio of red light and the degree/amount of reduction in the luminance ratio of green light may be similar to the degree/amount of reduction in the luminance ratio of blue light. For example, a deviation in the degree/amount of luminance ratio reduction between red light, green light, and blue light may be reduced. Thus, a WAD deviation in the first direction DR1 may be decreased, and the display quality of the display device DD (refer to FIG. 1) may be improved.

The first emissive region LA1 and the second emissive region LA2 may be spaced apart from the mesh pattern layer MP by certain gaps in a plan view. The first emissive region LA1 may be spaced apart from the third mesh line ML3 by a first gap d1 in a plan view, and the second emissive region LA2 may be spaced apart from the third mesh line ML3 by a second gap d2 in a plan view. The first gap d1 may correspond to the gap between the first emissive region LA1 and the first opening OP1, and the second gap d2 may correspond to the gap between the second emissive region LA2 and the second opening OP2.

The first emissive region LA1 and the second emissive region LA2 may be equally spaced apart from the mesh pattern layer MP in a plan view. For example, the first gap d1 and the second gap d2 may be substantially the same as each other.

The cut widths C-W of the first cut-away portion CT1 and the second cut-away portion CT2 may be set based on the average of the ratio of the first length L1 to the third length L3 and the ratio of the second length L2 to the third length L3, and therefore a deviation in the degree/amount of luminance ratio reduction between red light and green light based on the difference between the first length L1 and the second length L2 may occur. FIG. 10A illustrates the deviation (dev) in the degree/amount of luminance ratio reduction between red light and green light at a viewing angle of about 60 degrees.

As illustrated in FIG. 9C, the deviation (dev) in the degree/amount of luminance ratio reduction between red light and green light may be decreased by adjusting the first gap d1 and the second gap d2. For example, the first emissive region LA1 and the second emissive region LA2 may be differently spaced apart from the mesh pattern layer MP in a plan view. The first gap d1 may be increased to reduce the degree/amount of reduction in the luminance ratio of red light. Since the degree/amount of reduction in the luminance ratio of green light is relatively smaller than the degree/amount of reduction in the luminance ratio of red light, the second gap d2 may be smaller than the first gap d1. For example, the first gap d1 may be greater than the second gap d2.

FIG. 10B is a graph depicting luminance ratios depending on viewing angles of the display device including the mesh pattern layer of FIG. 9C. FIG. 10B illustrates luminance ratios of light beams emitted from the first to third emissive regions LA1, LA2, and LA3 depending on viewing angles in a direction parallel to the first direction DR1.

Referring to FIGS. 9C and 10B, since the first gap d1 and the second gap d2 are formed to be different from each other in consideration of the degrees of reduction in luminance ratios depending on color light beams, the deviation (dev) in the degree/amount of luminance ratio reduction between red light and green light may be decreased. As compared to those in the embodiment of FIG. 9B, the first gap d1 may be increased, and the second gap d2 may be decreased. Accordingly, although the occlusion (or blocking) of green light occurs first and the viewing angle at which the luminance ratio of green light starts to decrease is about 40 degrees, the overall deviation in the degree/amount of luminance ratio reduction between red light and green light may be reduced. Thus, a WAD deviation depending on viewing angles may be decreased, and the display quality of the display device DD (refer to FIG. 1) may be improved.

Referring again to FIG. 9A, the first emissive regions LA1 and the second emissive regions LA2 arranged in the first direction DR1 may be defined as a first light emission column C1, and the third emissive regions LA3 arranged in the first direction DR1 may be defined as a second light emission column C2. One first light emission column C1 and one second light emission column C2 adjacent to each other in the second direction DR2 may be defined as a pixel column PCn. The display panel DP (refer to FIG. 3) may include pixel columns PCn arranged in the second direction DR2.

The cut-away portions CT may not be formed in some of the second mesh lines ML2 and the third mesh lines ML3 positioned between the first emissive regions LA1 and the second emissive regions LA2. In case that the cut-away portions CT are formed in all of the second and third mesh lines ML2 and ML3 positioned between the first emissive regions LA1 and the second emissive regions LA2, the mesh pattern layer MP may be broken, and therefore the sensing parts SP1 and SP2 (refer to FIG. 5) may not be formed.

The cut widths C-W of the cut-away portions CT may be extended in consideration of the ratio of the second and third mesh lines ML2 and ML3 having the cut-away portions CT formed therein to the second and third mesh lines ML2 and ML3 positioned between the first emissive regions LA1 and the second emissive regions LA2. For example, within the range of Inequality 1 above or at the cut width C-W calculated by Equation 1 above, the cut widths C-W of the cut-away portions CT may be extended so as to be inversely proportional to the ratio of the second and third mesh lines ML2 and ML3 in which the cut-away portions CT are not formed to the second and third mesh lines ML2 and ML3 positioned between the first emissive regions LA1 and the second emissive regions LA2. For example, the extended cut widths may satisfy Equation 2 below. However, in an embodiment, the cut widths C-W may be extended so as to be equal to or smaller than the mesh width M-W.

$$Extended Cut Width = Cut Width of Equation 1 \times \frac{b}{a} \qquad [ Equation 2 ]$$

In Equation 2 above, “a” corresponds to the number of second and third mesh lines ML2 and ML3 in which the cut-away portions CT are not formed, among the second and third mesh lines ML2 and ML3 positioned between the first emissive regions LA1 and the second emissive regions LA2, and “b” corresponds to the total number of second and third mesh lines ML2 and ML3 positioned between the first emissive regions LA1 and the second emissive regions LA2.

Among the second and third mesh lines ML2 and ML3 positioned between the first emissive regions LA1 and the second emissive regions LA2, the mesh lines in which the cut-away portions CT are not formed may be alternately disposed in the second direction DR2. In case that the mesh lines in which the cut-away portions CT are not formed among the second and third mesh lines ML2 and ML3 are disposed side by side in the second direction DR2, the degrees of reduction in the luminance ratios of red light and green light may be different from each other in an upper direction and a lower direction parallel to the first direction DR1. However, in case that the mesh lines in which the cut-away portions CT are not formed among the second and third mesh lines ML2 and ML3 are alternately disposed in the second direction DR2, the deviation in the degree/amount of luminance ratio reduction depending on the upper direction and the lower direction may be reduced.

For example, the positions in which the cut-away portions CT are formed in portions of the mesh pattern layer MP that correspond to odd-numbered pixel columns PCn may differ from the positions in which the cut-away portions CT are formed in portions of the mesh pattern layer MP that correspond to even-numbered pixel columns PCn.

The cut-away portions CT may not be formed in some of the second mesh lines ML2 among the second and third mesh lines ML2 and ML3 disposed in the first light emission columns C1 of the odd-numbered pixel columns PCn. Among the second mesh lines ML2 disposed in the first light emission columns C1 of the odd-numbered pixel columns PCn, the second mesh lines ML2 in which the first cut-away portions CT1 are defined and the second mesh lines ML2 in which the cut-away portions CT are not defined may be alternately arranged in the first direction DR1.

The cut-away portions CT may not be formed in some of the third mesh lines ML3 among the second and third mesh lines ML2 and ML3 disposed in the first light emission columns C1 of the even-numbered pixel columns PCn. Among the third mesh lines ML3 disposed in the first light emission columns C1 of the even-numbered pixel columns PCn, the third mesh lines ML3 in which the second cut-away portions CT2 are defined and the third mesh lines ML3 in which the cut-away portions CT are not defined may be alternately arranged in the first direction DR1.

However, the positions of the cut-away portions CT illustrated in FIG. 9A are examples, and the positions in which the cut-away portions CT are formed are not limited thereto.

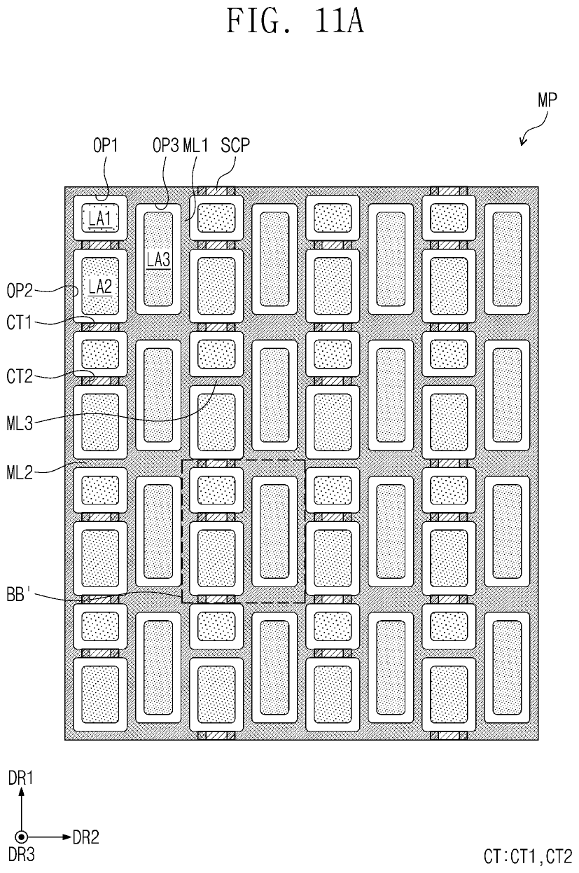

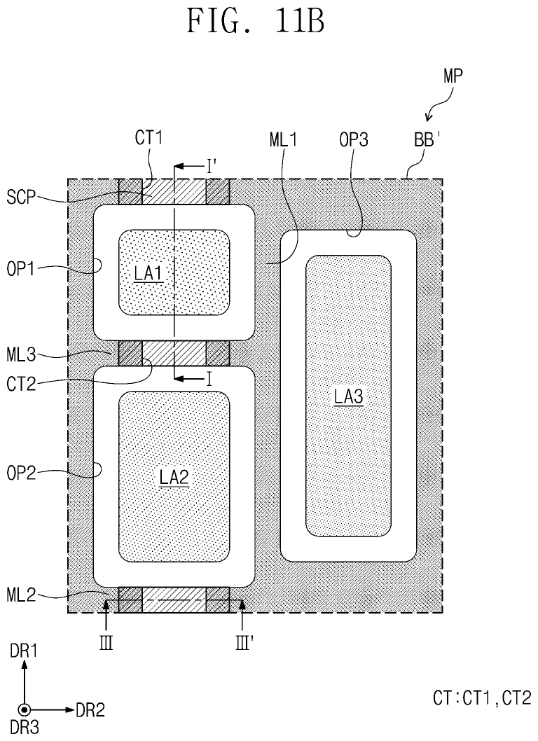

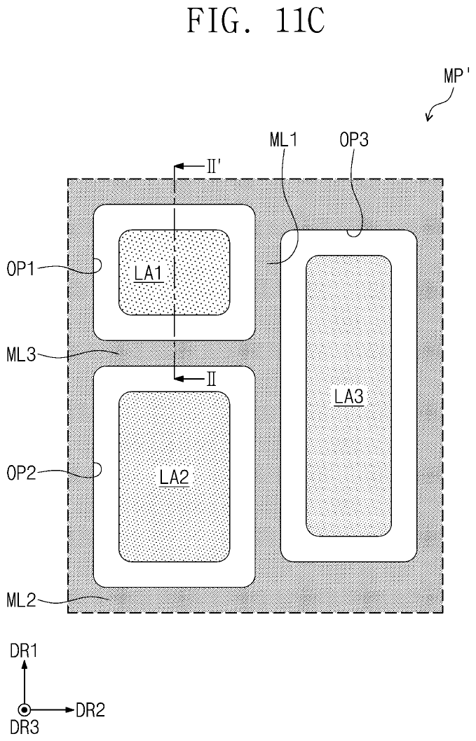

FIG. 11A is a schematic plan view of a mesh pattern layer MP according to an embodiment. FIG. 11B is an enlarged schematic plan view of the mesh pattern layer MP corresponding to a region BB′ of FIG. 11A. FIG. 11C is an enlarged schematic plan view of the mesh pattern layer MP′ of FIG. 7.

The mesh pattern layer MP of FIGS. 11A and 11B includes substantially the same components as the mesh pattern layer MP of FIGS. 9A and 9B. However, the mesh pattern layer MP of FIGS. 11A and 11B differs from the mesh pattern layer MP of FIGS. 9A and 9B in that the mesh pattern layer MP of FIGS. 11A and 11B further includes sub-conductive pattern layers SCP. The mesh pattern layer MP′ of FIG. 11C includes substantially the same components as the mesh pattern layer MP′ of FIG. 7. The above description may be applied to the same components, and the following description will be focused on the difference.

Referring to FIGS. 11A and 11B, the mesh pattern layer MP may further include the sub-conductive pattern layers SCP. Each of the sub-conductive pattern layers SCP may extend in the second direction DR2. The sub-conductive pattern layers SCP may be disposed to overlap cut-away portions CT.

The sub-conductive pattern layers SCP may be disposed on a layer different from first to third mesh lines ML1, ML2, and ML3. In a plan view, each of the sub-conductive pattern layers SCP may overlap a portion of the second mesh line ML2 or the third mesh line ML3 in which a corresponding cut-away portion CT is defined. Each of the sub-conductive pattern layers SCP may be connected to the overlapping second mesh line ML2 or the overlapping third mesh line ML3 through a contact hole.

The sub-conductive pattern layers SCP may include a conductive material. The sub-conductive pattern layers SCP and the first to third mesh lines ML1, ML2, and ML3 may include the same material. However, without being limited thereto, the sub-conductive pattern layers SCP may include a material different from that of the first to third mesh lines ML1, ML2, and ML3. The sub-conductive pattern layers SCP and the first to third mesh lines ML1, ML2, and ML3 may be connected (e.g., electrically connected) to each other and may transmit electrical signals transmitted to the sensing parts SP1 and SP2 (refer to FIG. 5).

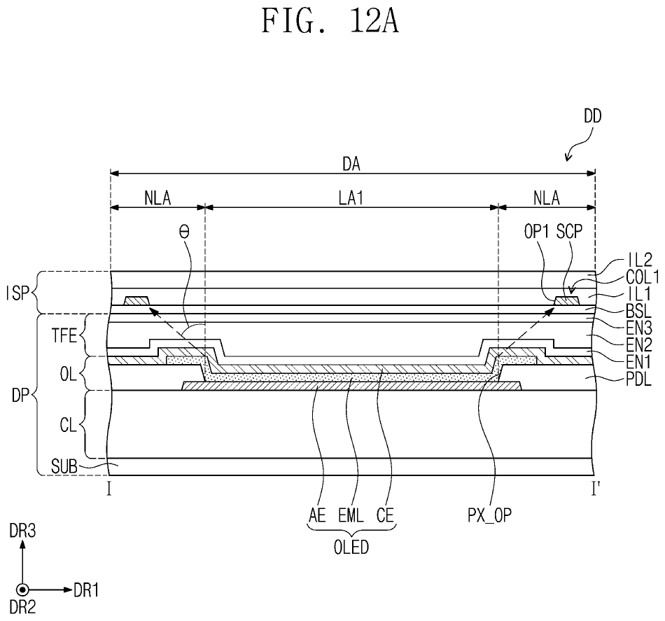

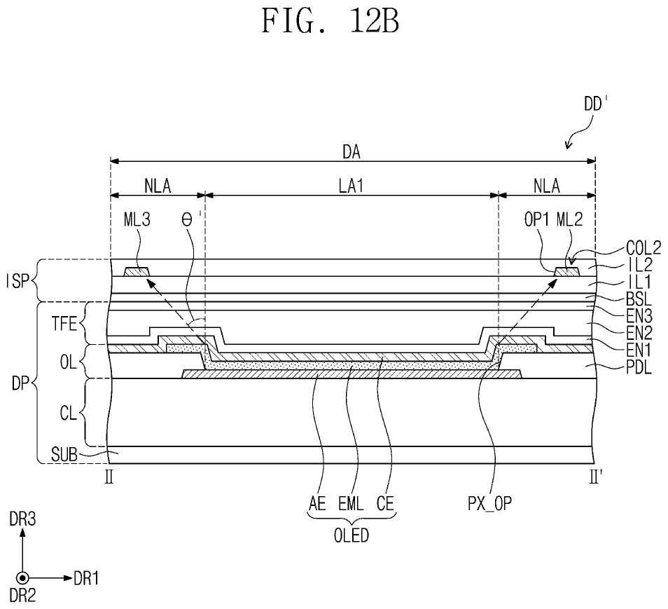

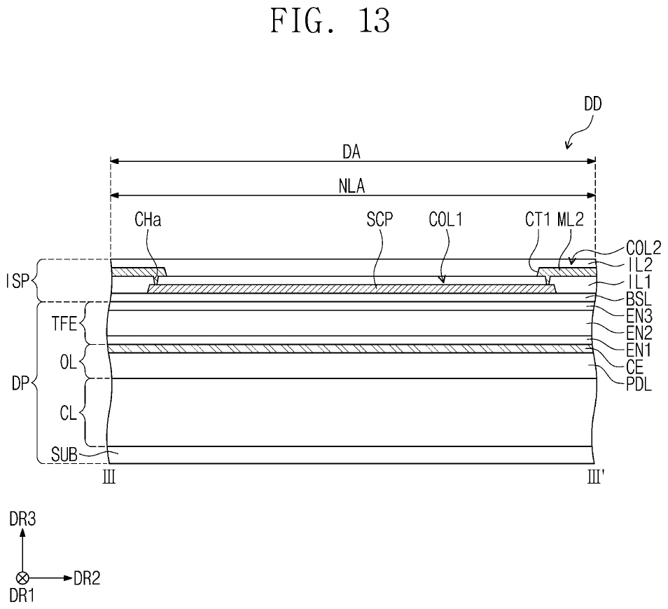

The line resistance of the mesh lines ML1, ML2, and ML3 may be reduced by the cut-away portions CT, and since the mesh pattern layer MP further includes the sub-conductive pattern layers SCP, the reduced line resistance may be compensated for. For example, the sub-conductive pattern layers SCP may be disposed below the mesh lines ML1, ML2, and ML3. Thus, a luminance ratio reduction by the mesh pattern layer MP may be improved as compared to that caused by the mesh pattern layer MP′ of FIG. 11C that does not include the cut-away portions CT and the sub-conductive pattern layers SCP. Detailed description thereabout will be given below with reference to FIGS. 12A and 12B.

FIG. 12A is a schematic sectional view of the display device DD taken along line I-I′ of FIG. 11B parallel to the first direction DR1, where the display device DD includes the mesh pattern layer MP according to an embodiment, and FIG. 12B is a schematic sectional view of a display device DD′ taken along line II-II′ of FIG. 11C parallel to the first direction DR1, where the display device DD′ includes the mesh pattern layer MP′ according to the comparative example.

FIGS. 12A and 12B illustrate sections corresponding to the first emissive region LA1 as an example. The following description will be given based on this, but the description may also be applied to a section corresponding to the second emissive region LA2.

Referring to FIG. 12A, the display device DD may include the display panel DP and the input sensing layer ISP disposed on the display panel DP. The display panel DP may include the base substrate SUB, the circuit element layer CL, the display element layer OL, and the thin film encapsulation layer TFE. The display element layer OL may include the pixel defining layer PDL and the light emitting element OLED, and the light emitting element OLED may include the first electrode AE, the emissive layer EML, and the second electrode CE. The above description may be applied to the components.

The thin film encapsulation layer TFE may include thin films EN1, EN2, and EN3. The first thin film EN1 may be disposed on the display element layer OL. The second thin film EN2 may be disposed on the first thin film EN1, and the third thin film EN3 may be disposed on the second thin film EN2.

Each of the first to third thin films EN1, EN2, and EN3 may include an inorganic film or an organic film. For example, the first thin film EN1 and the third thin film EN3 may include an inorganic film, and the second thin film EN2 may include an organic film. The inorganic film may protect the light emitting element OLED from moisture or oxygen, and the organic film may protect the light emitting element OLED from foreign matter such as dust particles.

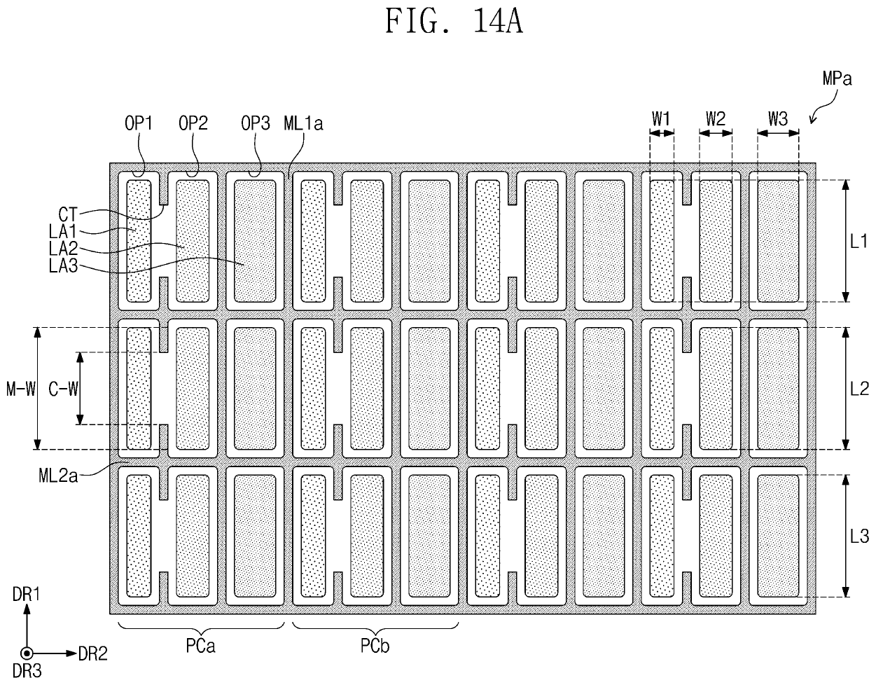

The input sensing layer ISP may be disposed on the thin film encapsulation layer TFE. In an embodiment, the input sensing layer ISP may be formed (e.g., directly formed) on a base surface provided by the thin film encapsulation layer TFE. The input sensing layer ISP may include a base layer BSL, a first conductive layer COL1, a first sensing insulation layer IL1, a second conductive layer COL2 (refer to FIG. 13), and a second sensing insulation layer IL2.

The base layer BSL may be disposed on the thin film encapsulation layer TFE. The base layer BSL may include at least one inorganic insulating layer. The base layer BSL may make contact with the thin film encapsulation layer TFE. However, without being limited thereto, the base layer BSL may be omitted in another example. For example, the first conductive layer COL1 may make contact with the thin film encapsulation layer TFE.

The first conductive layer COL1 may be disposed on the base layer BSL. The first conductive layer COL1 may include the sub-conductive pattern layers SCP. For example, the sub-conductive pattern layers SCP may be disposed on the base layer BSL.

The sub-conductive pattern layers SCP may be disposed in the non-emissive region NLA. The sub-conductive pattern layers SCP may be spaced apart from each other and may define the first opening OP1 overlapping the first emissive region LA1. The planar area of the first opening OP1 may be greater than the area of the first emissive region LA1, and the light emission efficiency of light emitted from the first emissive region LA1 may be prevented from being decreased by the sub-conductive pattern layers SCP.

The first sensing insulation layer IL1 may be disposed on the base layer BSL to cover the sub-conductive pattern layers SCP of the first conductive layer COL1. The second sensing insulation layer IL2 may be disposed on the first sensing insulation layer IL1. The first sensing insulation layer IL1 and the second sensing insulation layer IL2 may include an inorganic insulating layer or an organic insulating layer.

Referring to FIG. 12B, since the sub-conductive pattern layers SCP are not included, the second and third mesh lines ML2 and ML3 may be disposed on the regions on which the sub-conductive pattern layers SCP are disposed. The second and third mesh lines ML2 and ML3 may be included in the second conductive layer COL2 disposed on the first sensing insulation layer IL1. For example, the second and third mesh lines ML2 and ML3 may be disposed on the first sensing insulation layer IL1.

Referring to FIGS. 12A and 12B, in the embodiment in which the cut-away portions CT (refer to FIG. 11A) are formed in a portion where the second and third mesh lines ML2 and ML3 are disposed and the sub conductive pattern layers SCP are disposed to correspond to the cut-away portions CT (refer to FIG. 11A), the viewing angle Θ at which light starts to be occluded (or blocked) may be increased, and the luminance ratio reduction may be improved, unlike in the comparative example.

In the input sensing layer ISP, the sub-conductive pattern layers SCP may be disposed in a lower position than the second and third mesh lines ML2 and ML3. For example, the second and third mesh lines ML2 and ML3 may be disposed above the first sensing insulation layer IL1, and the sub-conductive pattern layers SCP may be disposed below the first sensing insulation layer IL1. Thus, the height of a conductor affecting the occlusion (or blocking) of light emitted from the light emitting element OLED may be decreased, and the viewing angle Θ at which light starts to be occluded (or blocked) by the conductor may be increased. For example, the sub-conductive pattern layers SCP may be positioned below the second and third mesh lines ML2 and ML3 by the thickness of the first sensing insulating layer IL1, and thus the viewing angle Θ at which light starts to be occluded (or blocked) by the sub-conductive pattern layers SCP may be greater than the viewing angle Θ′ at which light starts to be occluded (or blocked) by the second and third mesh lines ML2 and ML3. Accordingly, a reduction in the luminance of the display device DD may be improved, and the display quality may be improved.

FIG. 13 is a schematic sectional view of the display device DD corresponding to line III-III′ of FIG. 11B. The above description may be applied to components illustrated in FIG. 13.

Referring to FIG. 13, the first conductive layer COL1 of the input sensing layer ISP may include the sub-conductive pattern layer SCP, and the second conductive layer COL2 may include the mesh lines ML1, ML2, and ML3 (refer to FIG. 11A). FIG. 13 illustrates the region where the second mesh line ML2 is disposed. The first sensing insulation layer IL1 may be disposed between the sub-conductive pattern layer SCP and the second mesh line ML2 in the thickness direction of the display device DD (e.g., the third direction DR3).

The sub-conductive pattern layer SCP may be disposed in the non-emissive region NLA. The sub-conductive pattern layer SCP may extend in the second direction DR2 and may be disposed to correspond to a cut-away portion (e.g., the first cut-away portion CT1). For example, the sub-conductive pattern layer SCP may overlap the first cut-away portion CT1.

The sub-conductive pattern layer SCP may overlap a portion of the second mesh line ML2. The sub-conductive pattern layer SCP may be connected to the overlapping portion of the second mesh line ML2 through a contact hole CHa penetrating (or passing through) the first sensing insulation layer IL1.

Likewise, the sub-conductive pattern layer SCP may overlap the second cut-away portion CT2 (refer to FIG. 11A) defined in the third mesh line ML3 (refer to FIG. 11A) and a portion of the third mesh line ML3 (refer to FIG. 11A). The sub-conductive pattern layer SCP overlapping the second cut-away portion CT2 (refer to FIG. 11A) may be connected to the third mesh line ML3 (refer to FIG. 11A) through the contact hole CHa penetrating (or passing through) the first sensing insulation layer IL1.

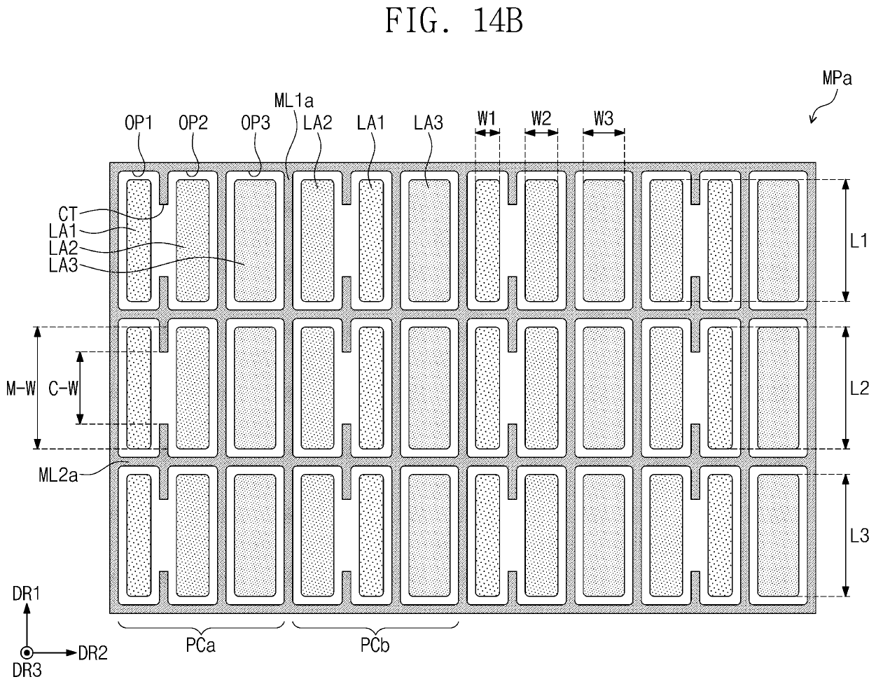

FIGS. 14A and 14B are schematic plan views of a mesh pattern layer MPa according to an embodiment.

Referring to FIG. 14A, the mesh pattern layer MPa may be a component of the first sensing parts SP1 (refer to FIG. 5) or the second sensing parts SP2 (refer to FIG. 5) described above. The mesh pattern layer MPa may include first mesh lines ML1a and second mesh lines ML2a that define first to third openings OP1, OP2, and OP3.

Each of the first mesh lines ML1a may extend in the first direction DR1, and the first mesh lines ML1a may be arranged in the second direction DR2. Each of the second mesh lines ML2a may extend in the second direction DR2, and the second mesh lines ML2a may be arranged in the first direction DR1. The second mesh lines ML2a may have an integral shape that intersects the first mesh lines ML1a in a plan view.

Each of the first to third openings OP1, OP2, and OP3 may be defined by being surrounded by the first mesh lines ML1a and the second mesh lines ML2a. The first to third openings OP1, OP2, and OP3 may have different areas in a plan view. For example, among the first to third openings OP1, OP2, and OP3, the third opening OP3 may have the largest planar area, and the first opening OP1 may have the smallest planar area. The regions in which the first to third openings OP1, OP2, and OP3 are defined may be regions overlapping first to third emissive regions LA1, LA2, and LA3.

The first to third emissive regions LA1, LA2, and LA3 may emit light beams having different colors. For example, the first emissive region LA1 may emit red light, the second emissive region LA2 may emit green light, and the third emissive region LA3 may emit blue light.

A plurality of first emissive regions LA1, a plurality of second emissive regions LA2, and a plurality of third emissive regions LA3 may be provided. The first emissive regions LA1, the second emissive regions LA2, and the third emissive regions LA3 may be arranged in a certain arrangement in a plan view. The first emissive regions LA1, the second emissive regions LA2, and the third emissive regions LA3 may be arranged in the first direction DR1. The first to third emissive regions LA1, LA2, and LA3 may be alternately arranged in the second direction DR2 in the order of the first emissive region LA1, the second emissive region LA2, and the third emissive region LA3.

The display panel DP (refer to FIG. 4) may include pixel columns PCa and PCb into which the first to third emissive regions LA1, LA2, and LA3 are grouped. Each of the pixel columns PCa and PCb may include one first light emission column defined as first emissive regions LA1 arranged in the first direction DR1, one second light emission column defined as second emissive regions LA2 arranged in the first direction DR1, and one third light emission column defined as third emissive regions LA3 arranged in the first direction DR1.

The pixel columns PCa and PCb may be arranged in the second direction DR2. In the embodiment illustrated in FIG. 14A, the arrangement of the first to third emissive regions LA1, LA2, and LA3 in the pixel columns PCa and PCb adjacent to each other in the second direction DR2 may be the same as each other.

The first to third openings OP1, OP2, and OP3 may overlap the first to third emissive regions LA1, LA2, and LA3, respectively. The first to third openings OP1, OP2, and OP3 may have planar areas greater than the areas of the overlapping emissive regions. For example, the planar area of the first opening OP1 may be greater than the area of the first emissive region LA1, the planar area of the second opening OP2 may be greater than the area of the second emissive region LA2, and the planar area of the third opening OP3 may be greater than the area of the third emissive region LA3. Thus, the mesh pattern layer MPa may not decrease the light emission efficiency of light emitted through the emissive regions LA1, LA2, and LA3.

In a plan view, some of the first mesh lines ML1a may be disposed between the first emissive region LA1 and the second emissive region LA2, other first mesh lines ML1a may be disposed between the second emissive region LA2 and the third emissive region LA3, and the other first mesh lines ML1a may be disposed between the third emissive region LA3 and the first emissive region LA1. The second mesh lines ML2a may be disposed between the first to third emissive regions LA1, LA2, and LA3 facing each other in the second direction DR2.

For convenience of description, the first and second mesh lines ML1a and ML2a are distinguished from each other. However, the first and second mesh lines ML1a and ML2a may be formed by patterning the first to third openings OP1, OP2, and OP3 in an integral conductive layer and may have an integral shape.

The first emissive region LA1 may have a first length L1 in the first direction DR1 and may have a first width W1 in the second direction DR2. The second emissive region LA2 may have a second length L2 in the first direction DR1 and may have a second width W2 in the second direction DR2. The third emissive region LA3 may have a third length L3 in the first direction DR1 and may have a third width W3 in the second direction DR2.

The lengths L1, L2, and L3 of the first to third emissive regions LA1, LA2, and LA3 in the first direction DR1 may be substantially the same as one another. For example, the first length L1, the second length L2, and the third length L3 may be substantially the same as one another.

The first to third widths W1, W2, and W3 of the first to third emissive regions LA1, LA2, and LA3 in the second direction DR2 may differ from one another. For example, the widths may increase in the order of the first width W1, the second width W2, and the third width W3. The first width W1 may be greater than the second width W2, and the second width W2 may be greater than the third width W3. A difference between the first to third widths W1, W2, and W3 may be greater than a difference between the first to third lengths L1, L2, and L3.

The first mesh lines ML1a of the mesh pattern layer MPa that extend in the first direction DR1 and that are arranged in the second direction DR2 may affect a luminance ratio reduction depending on viewing angles in the second direction DR2. Due to the mesh pattern layer MPa surrounding the first to third emissive regions LA1, LA2, and LA3 and the difference between the first to third widths W1, W2, and W3 of the first to third emissive regions LA1, LA2, and LA3, the degree/amount of reduction in luminance depending on viewing angles in the second direction DR2 may vary depending on light emission colors. For example, the degree/amount of reduction in the luminance ratio of red light and the degree/amount of reduction in the luminance ratio of green light may be greater than the degree/amount of reduction in the luminance ratio of blue light. However, by forming cut-away portions CT in at least one of the first mesh lines ML1a and the second mesh lines ML2a of the mesh pattern layer MPa, the deviation in the degree/amount of luminance ratio reduction depending on the light emission colors may be reduced.

The cut-away portions CT may be formed in the first mesh lines ML1a positioned between the first emissive region LA1 and the second emissive region LA2 in the second direction DR2 among the first mesh lines ML1a such that the degree/amount of reduction in the luminance ratio of red light and the degree/amount of reduction in the luminance ratio of green light are similar to the degree/amount of reduction in the luminance ratio of blue light. The first mesh lines ML1a having the cut-away portions CT defined therein may include a plurality of portions spaced apart from each other in the first direction DR1 by the cut-away portions CT.

The first emissive regions LA1 and the second emissive regions LA2 may be spaced apart from each other with the cut-away portions CT between the first emissive regions LA1 and the second emissive regions LA2 in a plan view. The cut-away portions CT may have an integral shape that is integral with adjacent openings among the openings OP1, OP2, and OP3. For example, as illustrated in FIG. 14A, each of the cut-away portions CT may be formed between the first opening OP1 and the second opening OP2 to connect the first opening OP1 and the second opening OP2 and may have an integral shape.

The cut-away portions CT may have cut widths C-W. The cut widths C-W may correspond to the sizes of portions that are removed from the first mesh lines ML1a to form the cut-away portions CT.

The cut widths C-W may vary depending on the first length L1 and the first width W1 of the first emissive region LA1, the second length L2 and the second width W2 of the second emissive region LA2, and the third width W3 of the third emissive region LA3. For example, the cut widths C-W may be set to be inversely proportional to a difference in width between the first emissive region LA1 and the third emissive region LA3 (e.g., a difference between the first width W1 and the third width W3) and a difference in width between the second emissive region LA2 and the third emissive region LA3 (e.g., a difference between the second width W2 and the third width W3).

The ratio of the cut width C-W to a mesh width M-W in the first direction DR1 may satisfy the range of Inequality 2 below. In an embodiment, the mesh width M-W may correspond to the length by which the first emissive region LA1 and the second emissive region LA2 overlap each other in the second direction DR2. For example, the mesh width M-W may be equal to the first length L1 or the second length L2. In Inequality 2 below, “W1”, “W2”, and “W3” may be the first width W1, the second width W2, and the third width W3, respectively.

$$1 - \frac{W 2}{W 3} \leq \frac{Cut Width ( C - W )}{Mesh Width ( M - W )} \leq 1 - \frac{W 1}{W 3} \qquad [ Inequality 2 ]$$

In an embodiment, the ratio of the cut width C-W to the mesh width M-W in the first direction DR1 may satisfy Equation 3 below. In Equation 3 below, “W1”, “W2”, and “W3” may be the first width W1, the second width W2, and the third width W3, respectively.

$$\frac{Cut Width ( C - W )}{Mesh Width ( M - W )} = 1 - \{ \frac{[ ( W 1 / W 3 ) + ( W 2 / W 3 ) ]}{2} \} \qquad [ Equation 3 ]$$

Since the cut-away portions CT are formed in portions of the first mesh lines ML1a located between the first emissive regions LA1 and the second emissive regions LA2, the degree/amount of reduction in the luminance ratio of red light and the degree/amount of reduction in the luminance ratio of green light may be reduced. For example, since the cut width C-W is designed in consideration of the ratio of the first width W1 to the third width W3 and the ratio of the second width W2 to the third width W3, a deviation in the degree/amount of luminance ratio reduction between red light, green light, and blue light may be decreased. Thus, a WAD deviation in the second direction DR2 may be decreased, and the display quality of the display device DD (refer to FIG. 1) may be improved.

In the embodiment of FIG. 14A, the pixel columns PCa and PCb adjacent to each other in the second direction DR2 include the first to third emissive regions LA1, LA2, and LA3 arranged in the same sequence, and therefore WAD in a left direction and WAD in a right direction may differ from each other.

For example, on the left side of the first emissive region LA1, light may be occluded (or blocked) by the first mesh line ML1a disposed between the first emissive region LA1 and the third emissive region LA3, and on the left side of the second emissive region LA2, light may not be substantially occluded (or blocked) by the first mesh line ML1a since the cut-away portion CT is formed on the left side of the second emissive region LA2. Accordingly, in the left direction, the degree/amount of reduction in the luminance ratio of green light may be smaller than the degree/amount of reduction in the luminance ratio of red light.

For example, on the right side of the second emissive region LA2, light may be occluded (or blocked) by the first mesh line ML1a disposed between the second emissive region LA2 and the third emissive region LA3, and on the right side of the first emissive region LA1, light may not be substantially occluded (or blocked) by the first mesh line ML1a since the cut-away portion CT is formed on the right side of the first emissive region LA1. Accordingly, in the right direction, the degree/amount of reduction in the luminance ratio of red light may be smaller than the degree/amount of reduction in the luminance ratio of green light. Thus, a WD deviation may occur in the left direction and the right direction.

To decrease the WAD deviation in the left direction and the right direction, the first to third emissive regions LA1, LA2, and LA3 included in the pixel columns PCa and PCb adjacent to each other in the second direction DR2 may be arranged in a different order as in the embodiment illustrated in FIG. 14B.

Referring to FIG. 14B, in the odd-numbered pixel columns PCa, the first to third emissive regions LA1, LA2, and LA3 may be arranged in the second direction DR2 in the order of the first emissive region LA1, the second emissive region LA2, and the third emissive region LA3. In the even-numbered pixel columns PCb adjacent to the odd-numbered pixel columns PCa in the second direction DR2, the positions of the first emissive regions LA1 and the positions of the second emissive regions LA2 may be interchanged. For example, in the even-numbered pixel columns PCb, the first to third emissive regions LA1, LA2, and LA3 may be arranged in the second direction DR2 in the order of the second emissive region LA2, the first emissive region LA1, and the third emissive region LA3.

Since the first emissive regions LA1 and the second emissive regions LA2 disposed in the pixel columns PCa and PCb adjacent to each other in the second direction DR2 are arranged in the different order, the WAD deviation in the left direction and the right direction may be decreased.

In the odd-numbered pixel columns PCa, the first mesh line ML1a in which the cut-away portion CT is not defined may be disposed on the left side of the first emissive region LA1, and in the even-numbered pixel columns PCb, the first mesh line ML1a having the cut-away portion CT defined therein may be disposed on the left side of the first emissive region LA1. In the odd-numbered pixel columns PCa, the first mesh line ML1a having the cut-away portion CT defined therein may be disposed on the right side of the first emissive region LA1, and in the even-numbered pixel columns PCb, the first mesh line ML1a in which the cut-away portion CT is not defined may be disposed on the right side of the first emissive region LA1. Accordingly, there may be little difference between the degree/amount of reduction in the luminance ratio of red light in the left direction and the degree/amount of reduction in the luminance ratio of red light in the right direction.

Likewise, in the odd-numbered pixel columns PCa, the first mesh line ML1a having the cut-away portion CT defined therein may be disposed on the left side of the second emissive region LA2, and in the even-numbered pixel columns PCb, the first mesh line ML1a in which the cut-away portion CT is not defined may be disposed on the left side of the second emissive region LA2. In the odd-numbered pixel columns PCa, the first mesh line ML1a in which the cut-away portion CT is not defined may be disposed on the right side of the second emissive region LA2, and in the even-numbered pixel columns PCb, the first mesh line ML1a having the cut-away portion CT defined therein may be disposed on the right side of the second emissive region LA2. Accordingly, there may be little difference between the degree/amount of reduction in the luminance ratio of green light in the left direction and the degree/amount of reduction in the luminance ratio of green light in the right direction.

In the disclosure, in consideration of a difference in length or width between emissive regions LA1, LA2, and LA3 in a direction, cut-away portions CT may be defined in portions of mesh lines ML1, ML2, and ML3 that form a sensing part. Accordingly, a deviation in the degree/amount of luminance ratio drop depending on viewing angles and light emission colors in the direction may be decreased, and a WAD deviation depending on viewing angles may be decreased. Thus, the display quality of a display device DD may be improved.

The input sensing layer ISP of the display device DD according to an embodiment may include the mesh pattern layer MP having the cut-away portions CT defined therein. The cut widths and positions of the cut-away portions CT of the mesh pattern layer MP may be designed in consideration of the difference in length between the emissive regions LA1, LA2, and LA3 in a direction.

Since the cut-away portions CT are defined in portions of the mesh pattern layer MP disposed over a light emitting element OLED, a deviation in luminance drop depending on viewing angles and light emission colors in the direction may be decreased. Thus, a deviation in white angular dependency (WAD) in which a white image is differently recognized depending on angles may be decreased, and the display quality of the display device DD may be improved.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a display panel including first, second, and third emissive regions; and
an input sensing layer disposed on the display panel and including sensing parts, the sensing parts including:
first, second, and third openings overlapping the first, second, and third emissive regions, respectively, and
a cut-away portion connecting the first opening and the second opening, wherein a cut width A of the cut-away portion satisfies Inequality 1:
$$1 - \frac{L 2}{L 3} \leq \frac{A}{B} \leq 1 - \frac{L 1}{L 3}$$
Here, L1 is a length of the first emissive region in a direction, L2 is a length of the second emissive region in the direction, L3 is a length of the third emissive region in the direction, and B is a length by which the first emissive region and the second emissive region overlap each other in the direction.

2. The display device of claim 1, wherein
the first emissive region, the second emissive region, and the third emissive region emit first color light, second color light, and third color light, respectively, and
the first color light, the second color light, and the third color light are different from one another.

3. The display device of claim 2, wherein a wavelength range of the third color light is smaller than a wavelength range of the first color light and a wavelength range of the second color light.

4. The display device of claim 2, wherein
the first emissive region and the second emissive region are arranged along a first direction, and
the third emissive region is arranged along a second direction intersecting the first direction from the first emissive region and the second emissive region.

5. The display device of claim 4, wherein
the direction corresponds to the first direction, and
L1 is less than or equal to L2.

6. The display device of claim 5, wherein
the first, second, and third emissive regions have first, second, and third widths, respectively, in the second direction, and
a difference between the first width and the third width is smaller than a difference between L1 and L3.

7. The display device of claim 5, wherein the cut width A satisfies Equation 1:
$$\frac{A}{B} = 1 - \{ \frac{[ ( \frac{L 1}{L 3} ) + ( \frac{L 2}{L 3} ) ]}{2} \}$$
Here, L1, L2, L3, and B are equal to L1, L2, L3, and B in Inequality 1.

8. The display device of claim 2, wherein
each of the first, second, and third emissive regions extends in a first direction, and
the first, second, and third emissive regions are alternately arranged along a second direction intersecting the first direction.

9. The display device of claim 8, wherein
the direction corresponds to the second direction, and
L1 is less than or equal to L2.

10. The display device of claim 9, wherein
the first, second, and third emissive regions have first, second, and third lengths, respectively, in the first direction, and
a difference between the first length and the third length is smaller than a difference between L1 and L3.

11. The display device of claim 1, wherein a gap between the first emissive region and the first opening is substantially equal to a gap between the second emissive region and the second opening.

12. The display device of claim 1, wherein a gap between the first emissive region and the first opening is greater than a gap between the second emissive region and the second opening.

13. The display device of claim 1, wherein
the sensing parts include mesh lines surrounding the first, second, and third openings in a plan view, and
the mesh lines have the cut-away portion and include a conductive material.

14. The display device of claim 13, wherein
the sensing parts further include a sub-conductive pattern layer overlapping the cut-away portion, and
the sub-conductive pattern layer is disposed on a layer different from the mesh lines and connected to the mesh lines through a contact hole.

15. A display device comprising:
a display panel including a plurality of pixel columns including first emissive regions, second emissive regions, and third emissive regions; and
an input sensing layer disposed on the display panel, the input sensing layer including sensing parts, wherein
the sensing parts include first openings, second openings, third openings, and cut-away portions,
the first openings overlap the first emissive regions, respectively,
the second openings overlap the second emissive regions, respectively, and
the third openings overlap the third emissive regions, respectively,
each of the cut-away portions connects a first opening and a second opening adjacent to each other among the first openings and the second openings, and
a cut width A of the cut-away portion satisfies Inequality 1:
$$1 - \frac{L 2}{L 3} \leq \frac{A}{B} \leq 1 - \frac{L 1}{L 3}$$
Here, L1 is a length of the first emissive region in a direction, L2 is a length of the second emissive region in the direction, L3 is a length of the third emissive region in the direction, and B is a length by which the first emissive region and the second emissive region overlap each other in the direction.

16. The display device of claim 15, wherein each of the plurality of pixel columns includes:
the first emissive regions arranged along a first direction;
the second emissive regions and the first emissive regions are alternatively arranged along the first direction; and
the third emissive regions spaced apart from the first emissive regions and the second emissive regions in a second direction intersecting the first direction and arranged along the first direction.

17. The display device of claim 16, wherein
the sensing parts include a mesh line in which the cut-away portions are not defined, the mesh line being disposed between the first emissive region and the second emissive region, and
some of the first openings and the second openings adjacent to each other in the first direction are spaced apart from each other with the mesh line disposed between the some of the first openings and the second openings adjacent to each other in the first direction.

18. The display device of claim 17, wherein
the plurality of pixel columns include an n^{th} pixel column and an (n+1)^{th} pixel column arranged along the second direction, where n is a natural number of 1 or larger, and
a position of the mesh line disposed in the n^{th} pixel column and a position of the mesh line disposed in the (n+1)^{th} pixel column are different from each other in the second direction.

19. The display device of claim 15, wherein each of the plurality of pixel columns includes:
the first emissive regions arranged along a first direction;
the second emissive regions spaced apart from the first emissive regions in a second direction intersecting the first direction and arranged along the first direction; and
the third emissive regions spaced apart from the first emissive regions in the second direction and arranged along the first direction.

20. The display device of claim 19, wherein
the plurality of pixel columns include an n^{th} pixel column and an (n+1)^{th} pixel column arranged along the second direction, where n is a natural number of 1 or larger,
in the n^{th} pixel column, the second emissive regions are disposed between the first emissive regions and the third emissive regions in the second direction, and
in the (n+1)^{th} pixel column, the first emissive regions are disposed between the second emissive regions and the third emissive regions in the second direction.
